(19) United States
(12) Patent Application Publication
(10) Pub. No.: US 2011/0073039 A1
(43) Pub. Date: Mar. 31, 2011

(54) SEMICONDUCTOR DEPOSITION SYSTEM AND METHOD

(76) Inventor: Ron Colvin, Gilbert, AZ (US)

(21) Appl. No.: 12/890,463

(22) Filed: Sep. 24, 2010

Related U.S. Application Data
(60) Provisional application No. 61/277,624, filed on Sep. 28, 2009.

(51) Int. Cl. H01L 21/36; H05B 1/02

(52) U.S. Cl. 118/725; 219/490

(57) ABSTRACT

A novel heating method and a novel gas inject schemes for a depositing semiconductor layers on wafers with improved disposition uniformity and disposition composition, deposition rates and decreased depletion rates. The novel heating and gas design can be readily changed in size to accommodate the ever increasing demand for larger substrates, increased batch sizes and increased deposition and heating efficiencies. The heating scheme can operate to 1500° C., and has a high resolution capability for tuning the temperature and gas flows for easy of setup and improved control and repeatability of the deposition process. This novel heating and gas inject scheme in conjunction with the unconventional usage of a non-quartz process chamber promises higher throughputs and higher wafer yields and reduced manufacturing costs for the manufacturing of silicon devices, silicon solar cells and white High Brightness LEDs.

### CROSS-REFERENCE TO RELATED APPLICATIONS

This application claims priority to U.S. Provisional Application No. 61/277,624, filed on Sep. 28, 2009 by the same inventor, the contents of which are incorporated by reference as though fully set forth herein.

### BACKGROUND OF THE INVENTION

1. Field of the Invention

This invention relates generally to providing heat and deposition gas control during the deposition of material on a wafer or substrate used for example in the production of High Brightness Light Emitting Diodes (LEDs semiconductor devices), solar cells and other semiconductor devices.

2. Description of the Related Art

A typical semiconductor device layer(s) may be elements or compounds such as GaN, InN, AlN or Si deposited on wafers using a deposition system. These layers of elements and or compounds are essential to technologies such as modern microelectronics, solar cells and LED devices.

It is desirable to increase the growth rate of the semiconductor material during the formation of the semiconductor layer so that more electronic devices and circuits can be formed in a given amount of time. It is desirable to control the uniformity of the semiconductor material allowing a number of identical electronic devices and circuits to be formed. The uniformity of the semiconductor material refers to the uniformity of its composition and the thickness of the layer. It is sometimes desirable to deposit semiconductor material that has the same composition from one location to another on the wafer. For example, it is known that gallium rich volumes are often undesirably formed when depositing gallium nitride. These gallium rich volumes can undesirably degrade the performance of an electronic device formed therewith.

A heater assembly is often used to heat the wafer in the presence of reactant gases that decompose and or combine chemically depositing a layer of semiconductor materials on wafers. There are many different types of heater assemblies that can be used to heat the wafer, such as those disclosed in U.S. Pat. Nos. 6,331,212 and 6,774,060. Some heater assemblies provide heat through induction heating, and others provide heat through resistance heating. Some heater assemblies, such as the one disclosed in U.S. Pat. No. 4,081,313, provide heat through infrared lamps.

However, there are several problems with deposition systems. One problem is the difficulty in uniformly heating the wafer(s) so that the semiconductor layers are deposited uniformly with a uniform composition. Another problem is controlling the process gases in order that the heated wafer(s) sees a composition of process gases that decompose and or combine so that the semiconductor layers are deposited uniformly with a uniform composition on the wafer. There is a crucial need in today's process requirements for epitaxial CVD, for systems with heating methods that provide improved wafer temperature control, uniformity and repeatability and reactant gas control and distribution over the wafer(s) so that semiconductor layers are deposited with improved film uniformity, higher throughput and a much reduced cost per wafer.

### BRIEF SUMMARY OF THE INVENTION

The present invention is directed to an apparatus for the chemical vapor deposition of semiconductor films specifically related to a novel heater assembly and gas introduction schemes. The novel features of the invention are set forth with particularity in the appended claims. The invention will be best understood from the following description when read in conjunction with the accompanying drawings.

### BRIEF DESCRIPTION OF THE DRAWINGS

FIG. 1a is a top view of one embodiment of a heater assembly 100

FIG. 1b is a side view of one embodiment of a heater assembly 100a along cut line 1b-1b of FIG. 1a

FIG. 1c is a side view of an embodiment of a heater assembly 100a along cut line 1b-1b of FIG. 1a

FIG. 1d is a side view of another embodiment of a heater assembly 100b along cut line 1b-1b of FIG. 1a

FIG. 1e is a representative heat/temperature profile of heater assembly 100 of FIG. 1b

FIG. 1f is a representative heat/temperature profile along cut line heater assembly 100a of FIG. 1c

FIG. 1g is a representative heat/temperature profile of a heater assembly

FIG. 2a is a top view of one embodiment of heater plate 110

FIG. 2b is a perspective view of heater plate 110

FIG. 2c is a cut-away side view of heater plate 110

FIG. 3a is a top view of inner segmented heater sub-assembly 120

FIG. 3b is a perspective view of segmented heater sub-assembly 120

FIG. 3c is side view of segmented heater sub-assembly 120

FIG. 3d is a side view of inner segmented heater sub-assembly 120 in a region 129 of FIG. 3c

FIG. 3e is a side view of another embodiment of inner segmented heater sub-assembly 120 in region 129

FIG. 3f is a perspective view of heater sub-assembly 120 in region 129,

FIG. 4a is a top view of one embodiment of intermediate segmented heater sub-assembly 140

FIG. 4b is a perspective view of intermediate segmented heater sub-assembly 140

FIG. 4c is a cut-away side view of intermediate segmented heater sub-assembly 140 in region 149

FIG. 4d is a side view of intermediate segmented heater sub-assembly 140 in region 149

FIG. 4e is a side view of another embodiment of intermediate segmented heater sub-assembly 140 in region 149

FIG. 4f is a perspective view of intermediate segmented heater sub-assembly 140 in region 149,

FIG. 5a is a top view of one embodiment of outer segmented heater sub-assembly 160

FIG. 5b is a perspective view of outer segmented heater sub-assembly 160

FIG. 5c is a cut-away side view of outer segmented heater sub-assembly 160

FIG. 5d is a side view of outer segmented heater sub-assembly 160 in a region 169

FIG. 5e is a side view of another embodiment of outer segmented heater sub-assembly 160

FIG. 6 is a top view of one embodiment of a heater assembly 100a

FIG. 7 is a top view of one embodiment of coiled heater 110

FIG. 8a is a perspective view of a heater coil 170

FIG. 8b is a top views of a heater coil 170

FIGS. 9a and 9b are perspective and top views, respectively, of another embodiment of a heater coil, denoted as heater coil 170a

FIGS. 10a and 10b are top and side views, respectively, of one embodiment of a coiled inner segmented heater assembly 181.

FIG. 11a and 11b are top and side views, respectively, of one embodiment of a coiled intermediate segmented heater assembly 182

FIGS. 12a and 12b are top and side views, respectively, of one embodiment of a coiled outer segmented heater assembly 100.

FIG. 13a is a top view of one embodiment of a heater assembly 100b

FIG. 13b is a top view of one embodiment of a heater assembly 100c

FIG. 13c is a top view of one embodiment of a heater assembly 100d

FIG. 13d is a top view of one embodiment of a heater assembly 100e

FIG. 13e is a top view of one embodiment of a heater assembly 100f

FIG. 14a is a cut-away side view of deposition system 200

FIG. 14b is cross sectional view of the interior of the deposition system 200

FIG. 14c is cross sectional plan view along cut line 14b-14b of FIG. 14b

FIG. 14d is a cross section plan view of heater array 100 along cut line 14b1-14b1 of FIG. 14b

FIG. 14e is an expanded view of the upper and lower heater assemblies 100 of deposition system 200

FIG. 14f is a thermal comparison of the embodiments herein versus two prior art technologies

FIG. 15a is a side cross-sectional view of reactor chamber and gas system of deposition system 200a.

FIG. 15b is an expanded cross sectional side view of the gas injection scheme as defined by region 219 of FIG. 14b.

FIG. 15c is a pictorial view of the one of the upstream gas inlet ports 226 and one of the downstream gas inlet ports 225.

FIG. 15d is an expanded view along cut line 15d-15d of FIG. 15c of the downstream gas inlet port 229

FIG. 15e is a plan view of the upstream gas injection embodiment of deposition system 200

FIG. 15f is a plan view of the downstream gas inject embodiment of deposition system 200

FIG. 16a is a cross sectional view of a vertical gas inject scheme of deposition system 200b

FIG. 16b is an exploded cross sectional view of a vertical gas inject scheme of deposition system 200b

FIG. 16c is a plan view of the upper plate of process chamber 204c a vertical gas inject scheme

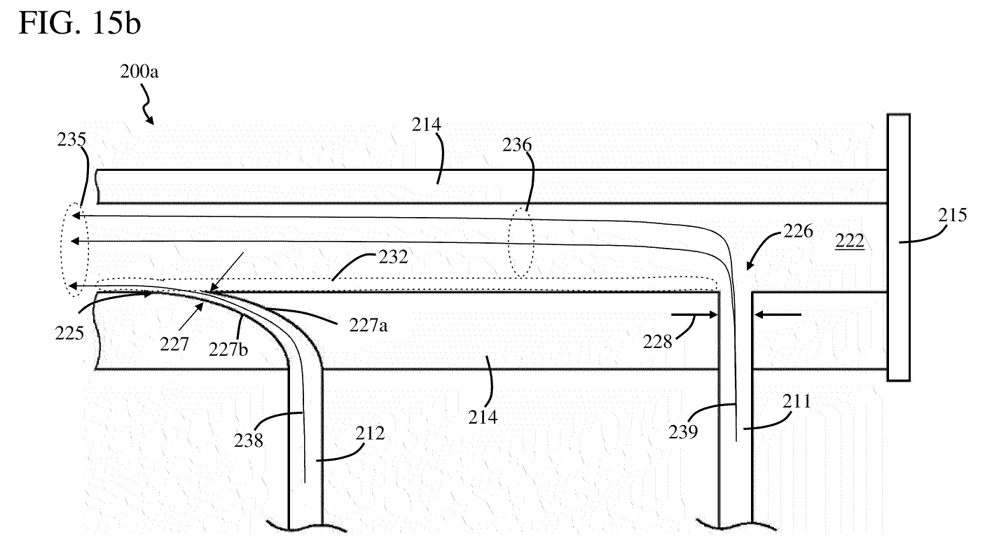

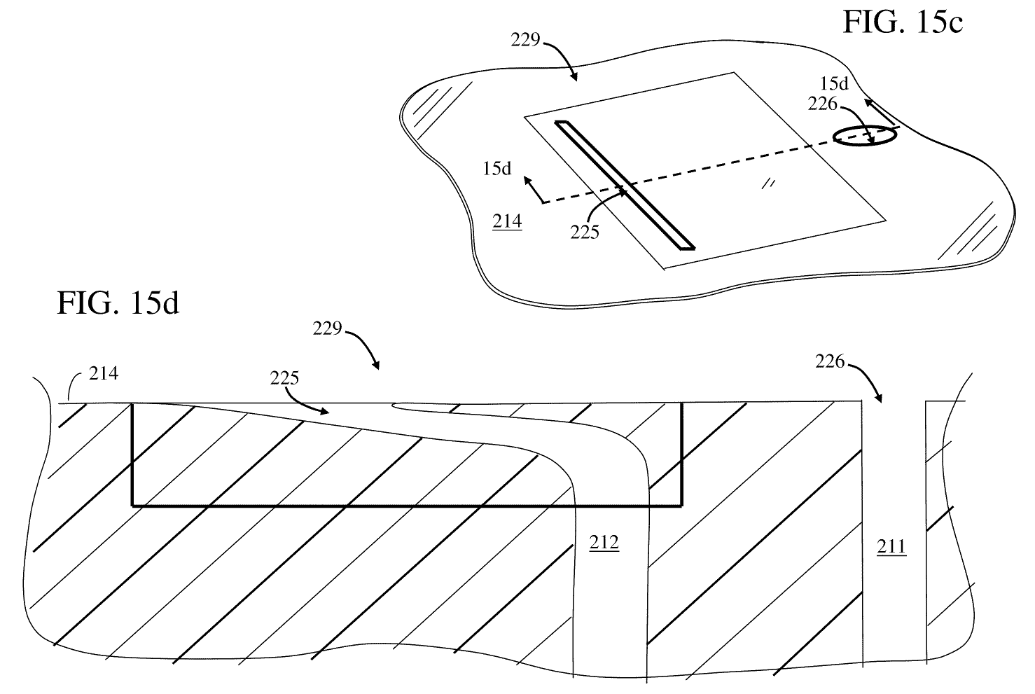

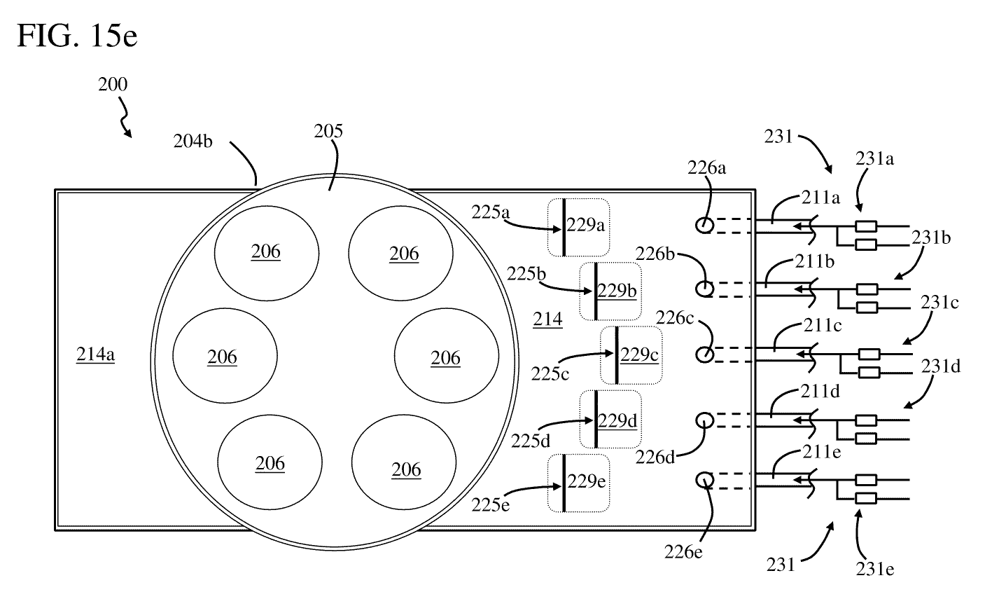

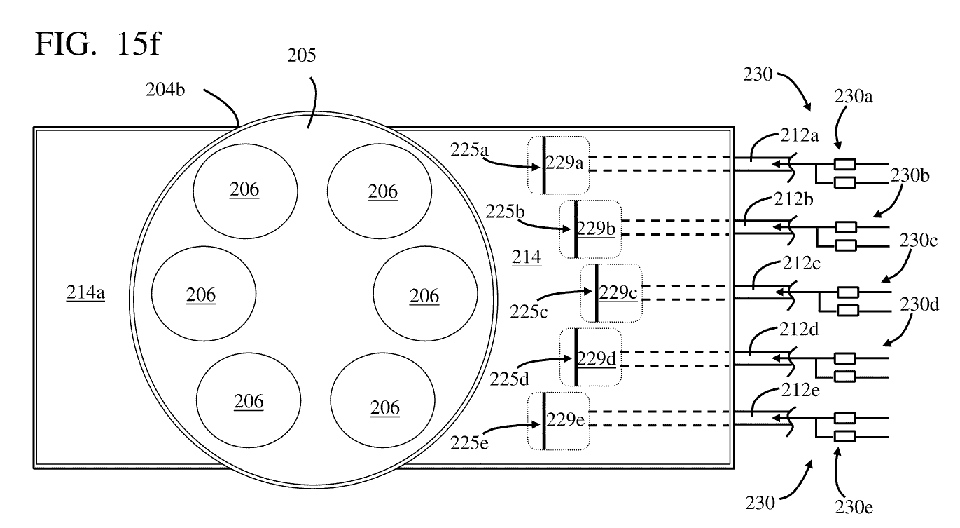

FIG. 15d is comparison of the depletion profile of prior art and the invention

### DETAILED DESCRIPTION OF THE INVENTION

Heater assemblies disclosed herein provide heat during the deposition of material on a wafer. The material is deposited using a deposition system, such as a CVD, MBE, HVPE or MOCVD system. The material deposited on the wafer can be of many different types, such as semiconductor material. Electronic devices and circuitry are often formed on the wafer, wherein the electronic device and circuitry utilize the material deposited.

The heater assemblies disclosed herein uniformly heat the wafer so that the material is deposited uniformly. Further, the material is deposited on the wafer at a faster rate so that more electronic devices and circuits can be formed in a given amount of time.

The heater assemblies disclosed herein heat the wafer uniformly so that the material being deposited has a more uniform composition. In this way, the material deposited on the wafer is driven to have the same composition at different locations of the wafer. This is useful so that the electronic devices and circuits at different locations of the wafer are driven to be identical.

The gas control, injection and distribution embodiments disclosed herein distribute process gases over wafer(s) more uniformly and with more control. The gases are distributed over areas of the wafer(s) being heated by the heater assemblies are controlled together so that material is deposited on the wafer more uniformly with a more uniform composition and at a faster rate.

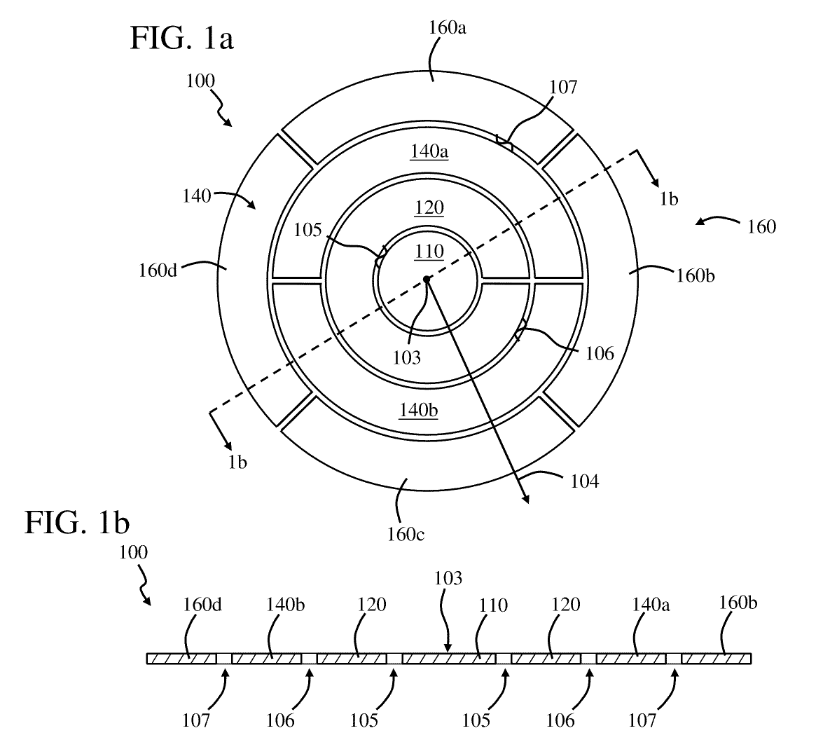

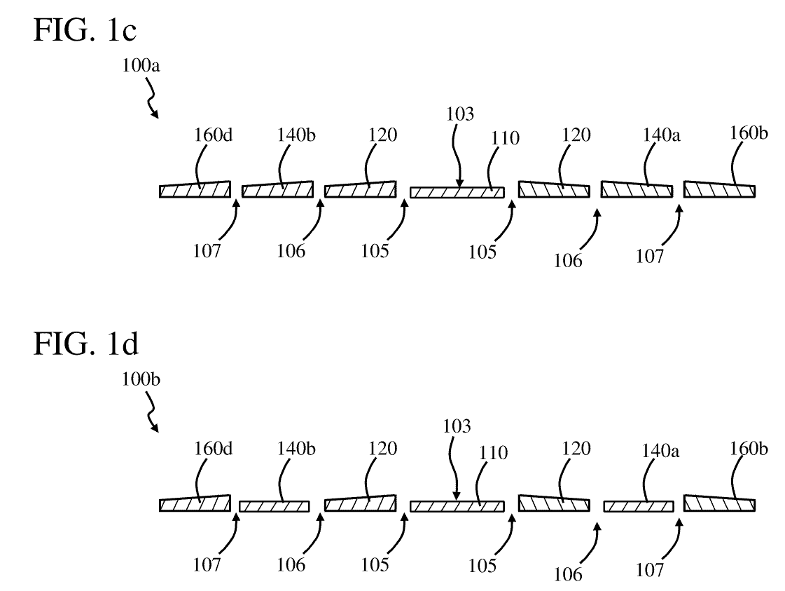

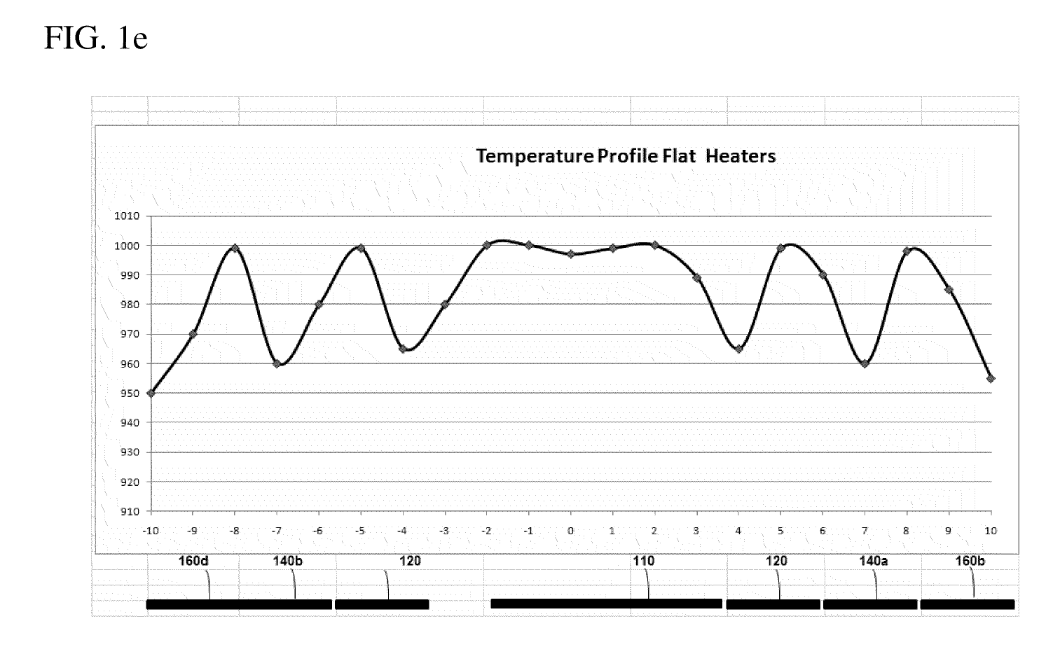

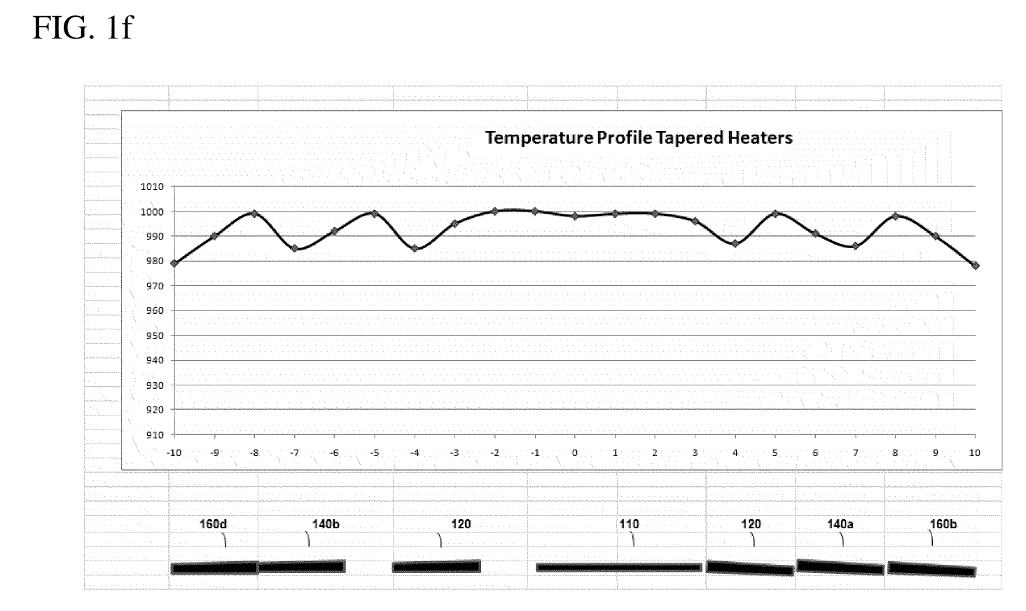

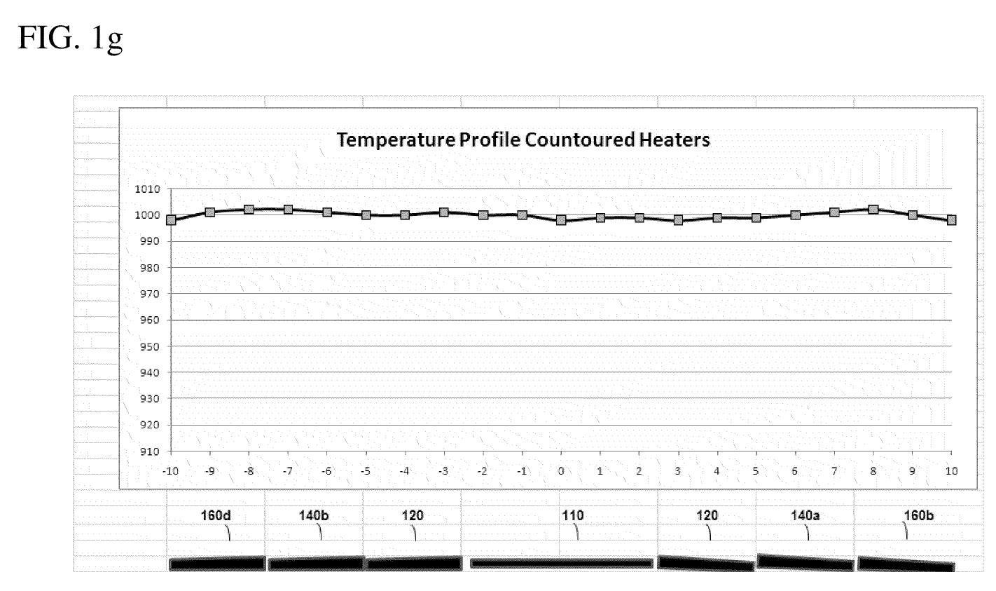

FIG. 1a is a top view of one embodiment of a heater assembly 100, and FIG. 1b is a cut-away side view of heater assembly 100 taken along a cut-line 1b-1b of FIG. 1a. In this embodiment, heater assembly 100 includes a heater plate sub-assembly 110, and an inner segmented heater sub-assembly 120 spaced from heater plate sub-assembly 110 by an inner annular gap 105. Inner annular gap 105 is dimensioned to prohibit the ability of current to flow between heater assemblies 110 and 120. It is desirable to prohibit the ability of current to flow between heater assemblies 110 and 120 so that different adjustable power signals can be provided to each. The center 103 of heater assembly 100 may be coincident with the center of heater plate sub-assembly 110.

It is desirable to provide different adjustable power signals to heater assemblies 110 and 120 so they provide different adjustable amounts of heat. The amount of heat provided by heater assemblies 110 and 120 is adjustable in response to adjusting the corresponding adjustable power signals. It is desirable for heater assemblies 110 and 120 to provide different adjustable amounts of heat so they are thermally decoupled from each other. The thermal coupling between heater assemblies 110 and 120 is adjustable in response to adjusting the corresponding adjustable power signal. It is desirable to thermally decouple heater assemblies 110 and 120 so the uniformity of the heat provided by heater assembly 100 can be better controlled. The uniformity of the heat provided by heater assembly 100 is adjustable in response to adjusting the corresponding adjustable power signal provided to heater assemblies 110 and 120.

In this embodiment, heater assembly 100 includes an intermediate segmented heater sub-assembly 140 consisting of intermediate heater segment 140a and 140b, spaced from inner segmented heater sub-assembly 120 by an intermediate annular gap 106. Intermediate annular gap 106 is dimensioned to inhibit the ability of current to flow between heater assemblies 120 and 140. It is desirable to inhibit the ability of current to flow between heater assemblies 110 and 120 so that different adjustable power signals can be provided to them.

It is desirable to provide different adjustable power signals to heater assemblies 120 and 140 so they provide different adjustable amounts of heat. The amount of heat provided by heater assemblies 120 and 140 is adjustable in response to adjusting the corresponding adjustable power signals. It is desirable for heater assemblies 120 and 140 to provide different adjustable amounts of heat so they are thermally decoupled from each other. The thermal coupling between heater assemblies 120 and 140 is adjustable in response to adjusting the corresponding adjustable power signal. It is desirable to thermally decouple heater assemblies 120 and 140 so the uniformity of the heat provided by heater assembly 100 can be better controlled. The uniformity of the heat provided by heater assembly 100 is adjustable in response to adjusting the corresponding adjustable power signal provided to heater assemblies 120 and 140.

In this embodiment, heater assembly 100 includes an outer segmented heater sub-assembly 160 consisting of outer heater segment 160a, 160b, 160c and 160d spaced from intermediate segmented heater sub-assembly 140 by an outer annular gap 107. Outer annular gap 107 is dimensioned to inhibit the ability of current to flow between heater assemblies 140 and 160. It is desirable to prohibit the ability of current to flow between heater assemblies 140 and 160 so that different adjustable power signals can be provided to them.

It is desirable to provide different adjustable power signals to heater sub-assemblies 140 and 160 so they provide different adjustable amounts of heat. The amount of heat provided by heater sub-assemblies 140 and 160 is adjustable in response to adjusting the corresponding adjustable power signals. It is desirable for heater sub-assemblies 140 and 160 to provide different adjustable amounts of heat so they are thermally decoupled from each other. The thermal coupling between heater sub-assemblies 140 and 160 is adjustable in response to adjusting the corresponding adjustable power signal. It is desirable to thermally decouple heater sub-assemblies 140 and 160 so the uniformity of the heat provided by heater assembly 100 can be better controlled. The uniformity of the heat provided by heater assembly 100 is adjustable in response to adjusting the corresponding adjustable power signal provided to heater sub-assemblies 140 and 160.

It should be noted that inner gap 105, intermediate gap 106 and outer gap 107 are annular gaps because they extend annularly around heater plate sub-assembly 110, inner segmented heater sub-assembly 120 and intermediate segmented heater sub-assembly 140, respectively.

In operation, different power signals are provided to heater plate sub-assembly 110, inner segmented heater sub-assembly 120, intermediate heater segment 140a and 140b of intermediate segmented heater sub-assembly 140 and outer heater sub-assembly 160a, 160b, 160c and 160d of outer segmented heater sub-assembly 160. Heater plate sub-assembly 110, inner segmented heater sub-assembly 120, intermediate segmented heater sub-assembly 140 and outer segmented heater sub-assembly 160 provide heat in response to receiving the corresponding power signal.

In one mode of operation, adjustable power signals are provided to heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160, wherein the adjustable power signals are adjusted to regulate the amount of heat provided by heater assembly 100.

For example, in one embodiment, the amount of heat provided by heater assembly 100 is adjusted in response to adjusting the phases of the power signals. In one particular embodiment, an alternating current power signal is provided to heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160. The phases of the alternating current power signals are adjusted relative to each other to adjust the amount of heat provided by heater assembly 100. In this way, the amount of heat provided by heater assembly 100 is regulated in response to adjusting the phases of the power signals.

In another embodiment, the amount of heat provided by heater assembly 100 is adjusted in response to adjusting the amplitudes of the power signals. In one particular embodiment, an alternating current power signal is provided to heater plate sub-assembly 110, inner segmented heater sub-assembly 120, intermediate heater segment 140a and 140b and outer heater segment 160a, 160b, 160c and 160d heater sub-assembly 160. In this embodiment, the alternating current power signals can have different phases. In one embodiment, the alternating current power signals are out of phase by 120 degrees. Alternating current power signals out of phase by 120 degrees are often used in three-phase systems, such as a three-phase motor. In this way, the amount of heat provided by heater assembly 100 is adjusted in response to adjusting the amplitudes of the power signals.

In one mode of operation, adjustable power signals are provided to heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160, wherein the adjustable power signals are adjusted to adjust the thermal coupling between heater plate sub-assembly 110, inner segmented heater sub-assembly 120, intermediate segmented heater sub-assembly 140 and outer segmented heater sub-assembly 160.

For example, in one embodiment, the thermal coupling between heater plate sub-assembly 110, inner segmented heater sub-assembly 120, intermediate segmented heater sub-assembly 140 and outer segmented heater sub-assembly 160 is adjusted in response to adjusting the phases of the power signals. In one particular embodiment, a direct current power signal is provided to heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160. The amplitude of the direct current power signals is adjusted relative to each other to adjust the thermal coupling between heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160. In this way, the thermal coupling between heater plate sub-assembly 110, inner segmented heater sub-assembly 120, intermediate segmented heater sub-assembly 140 and outer segmented heater sub-assembly 160 is adjusted in response to adjusting the amplitude of the power signals.

In another embodiment, the thermal coupling between heater plate sub-assembly 110, inner segmented heater sub-assembly 120, intermediate segmented heater sub-assembly 140 and outer segmented heater sub-assembly 160 is adjusted in response to adjusting the amplitudes of the power signals. In one particular embodiment, a direct current power signal is provided to heater plate sub-assembly 110, and alternating current power signals are provided to inner segmented heater sub-assembly 120, intermediate heater segment 140a and 140b of intermediate segmented heater sub-assembly 140 and outer heater segment 160a, 160b, 160c and 160d of outer segmented heater sub-assembly 160. In this embodiment, the alternating current power signals can have many different phases. In one embodiment, the alternating current power signals are out of phase by 120 degrees. Alternating current power signals out of phase by 120 degrees are often used in three-phase high power systems, such as a three-phase motor. In this way, the thermal coupling between heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160 is adjusted in response to adjusting the amplitudes of the power signals.

In one mode of operation, adjustable power signals are provided to heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160, wherein the adjustable power signals are adjusted to adjust the uniformity of the heat provided by heater assembly 100.

In one particular embodiment, a direct current power signal is provided to heater plate sub-assembly 110, and alternating current power signals are provided to inner segmented heater sub-assembly 120, intermediate segmented heater sub-assembly 140 and outer segmented heater sub-assembly 160. The phases of the alternating current power signals are adjusted relative to each other to adjust the uniformity of the heat provided by heater assembly 100. In this way, the uniformity of the heat provided by heater assembly 100 is regulated in response to adjusting the phases of power signals.

In another embodiment, the uniformity of the heat provided by heater assembly 100 is adjusted in response to adjusting the amplitudes of the power signals. In one particular embodiment, a direct current power signal is provided to heater plate sub-assembly 110, and alternating current power signals are provided to inner segmented heater sub-assembly 120, intermediate segmented heater sub-assembly 140 and outer segmented heater sub-assembly 160. In this embodiment, the alternating current power signals can have many different phases. In one embodiment, the alternating current power signals are out of phase by 120 degrees. Alternating current power signals out of phase by 120 degrees are often used in high power electrical systems, such as a three-phase motor. In this way, the uniformity of the heat provided by heater assembly 100 is adjusted in response to adjusting the amplitudes of the power signals.

It should also be noted that heater assembly 100, as shown in FIG. 1b, has a uniform thickness. Heater assembly 100 of FIG. 1b has a uniform thickness because the thicknesses of heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160 are the same thickness values between inner gap 105 and the outer periphery of outer segmented heater sub-assembly 160.

The thicknesses of heater plate sub-assembly 110, inner segmented heater sub-assembly 120, intermediate segmented heater sub-assembly 140 and outer segmented heater sub-assembly 160 are chosen to provide a desired resistance. The resistance of heater plate sub-assembly 110 increases and decreases as its thickness decreases and increases, respectively. The resistance of inner segmented heater sub-assembly 120 increases and decreases as its thickness decreases and increases, respectively. The resistance of intermediate heater segment 140a and 140b of intermediate segmented heater sub-assembly 140 increases and decreases as its thickness decreases and increases, respectively. The resistance outer heater segment 160a, 160b, 160c and 160d of outer segmented heater sub-assembly 160 increases and decreases as its thickness decreases and increases, respectively. It should be noted that, for a given amount of power, the amount of heat provided by a sub-assembly increases and decreases as its resistance increases and decreases, respectively.

FIG. 1c is a side view of a heater assembly 100a having a non-uniform thickness. Heater assembly 100a has a non-uniform thickness because it includes a sub-assembly having a non-uniform thickness. In this embodiment, heater assembly 100a has a non-uniform thickness because the thicknesses of inner segmented heater sub-assembly 120, intermediate heater segment 140a and 140b of intermediate segmented heater sub-assembly 140 and outer heater segment 160a, 160b, 160c and 160d of outer segmented heater sub-assembly 160 have thickness values that vary between inner gap 105 and the outer periphery of outer segmented heater sub-assembly 160. In this way, the intermediate heater segment 140a and 140b of intermediate segmented heater sub-assembly 140 and outer heater segment 160a, 160b, 160c and 160d of outer segmented heater sub-assembly 160 each have a non-uniform thickness.

The thicknesses of heater plate sub-assembly 110, inner segmented heater sub-assembly 120, intermediate heater segment 140a and 140b of intermediate segmented heater sub-assembly 140 and outer heater segment 160a, 160b, 160c and 160d of outer segmented heater sub-assembly 160 are chosen to provide a desired resistance. As mentioned above, the resistance of heater plate sub-assembly 110 increases and decreases as its thickness decreases and increases, respectively.

The resistance of inner segmented heater sub-assembly 120 increases and decreases as its thickness decreases and increases, respectively. In this embodiment, inner segmented heater sub-assembly 120 is thicker proximate to inner gap 105 and thinner proximate to intermediate gap 106. Inner segmented heater sub-assembly 120 is less resistive proximate to inner gap 105 because it is thicker proximate to inner gap 105. Further, inner segmented heater sub-assembly 120 is more resistive proximate to intermediate gap 106 because it is thinner proximate to intermediate gap 106. It is desirable to have inner segmented heater sub-assembly 120 less resistive proximate to inner gap 105 and more resistive proximate to intermediate gap 106 so that inner segmented heater sub-assembly 120 provides less heat proximate to inner gap 105 and more heat proximate to intermediate gap 106. It is desirable to have inner segmented heater sub-assembly 120 provide less heat proximate to inner gap 105 and more heat proximate to intermediate gap 106 because inner gap 105 is closer to center 103 than intermediate gap 106. In this way, inner segmented heater sub-assembly 120 provides a more uniform amount of heat.

The resistance of intermediate segmented heater sub-assembly 140 increases and decreases as its thickness decreases and increases, respectively. The resistance of intermediate segmented heater sub-assembly 140 increases and decreases as its thickness decreases and increases, respectively. In this embodiment, intermediate segmented heater sub-assembly 140 is thicker proximate to intermediate gap 106 and thinner proximate to outer gap 107. Intermediate segmented heater sub-assembly 140 is less resistive proximate to intermediate gap 106 because it is thicker proximate to intermediate gap 106. Further, intermediate segmented heater sub-assembly 140 is more resistive proximate to outer gap 107 because it is thinner proximate to outer gap 107. It is desirable to have intermediate segmented heater sub-assembly 140 less resistive proximate to intermediate gap 106 and more resistive proximate to outer gap 107 so that intermediate segmented heater sub-assembly 140 provides less heat proximate to intermediate gap 106 and more heat proximate to outer gap 107. It is desirable to have intermediate segmented heater sub-assembly 140 provide less heat proximate to intermediate gap 106 and more heat proximate to outer gap 107 because intermediate gap 106 is closer to center 103 than outer gap 107. In this way, intermediate segmented heater sub-assembly 140 provides a more uniform amount of heat.

The resistance of outer segmented heater sub-assembly 160 increases and decreases as its thickness decreases and increases, respectively. The resistance of outer segmented heater sub-assembly 160 increases and decreases as its thickness decreases and increases, respectively. In this embodiment, outer segmented heater sub-assembly 160 is thicker proximate to outer gap 107 and thinner proximate to the outer periphery of heater assembly 100. Outer segmented heater sub-assembly 160 is less resistive proximate to outer gap 107 because it is thicker proximate to outer gap 107. Further, outer segmented heater sub-assembly 160 is more resistive proximate to the outer periphery of heater assembly 100 because it is thinner proximate to the outer periphery of heater assembly 100. It is desirable to have outer segmented heater sub-assembly 160 less resistive proximate to outer gap 107 and more resistive proximate to the outer periphery of heater assembly 100 so that outer segmented heater sub-assembly 160 provides less heat proximate to outer gap 107 and more heat proximate to the outer periphery of heater assembly 100. It is desirable to have outer segmented heater sub-assembly 160 provide less heat proximate to outer gap 107 and more heat proximate to the outer periphery of heater assembly 100 because outer gap 107 is closer to center 103 than the outer periphery of heater assembly 100. In this way, outer segmented heater sub-assembly 160 provides a more uniform amount of heat.

FIG. 1d is a side view of a heater assembly 100b which includes a segmented heater assembly with a uniform thickness and another segmented heater assembly with a non-uniform thickness. For example, in this embodiment, heater assembly 100b includes heater plate 110 and intermediate segmented heater sub-assembly 140, as shown in FIG. 1a. In this embodiment, heater assembly 100b includes intermediate segmented heater sub-assembly 140, wherein intermediate segmented heater sub-assembly 140 has a non-uniform thickness. Intermediate segmented heater sub-assembly 140 is positioned between heater plate 110 and intermediate segmented heater sub-assembly 140. Further, heater assembly 100b includes outer segmented heater sub-assembly 160, wherein outer segmented heater sub-assembly 160 has a non-uniform thickness. Outer segmented heater sub-assembly 160 is positioned around intermediate segmented heater sub-assembly 140.

It should be noted that any of the heater assemblies discussed herein can include many different combinations of uniform and non-uniform segmented heater assemblies, but only a few are shown for simplicity and ease of discussion. The particular combination of uniform and non-uniform segmented heater assemblies depends on many different factors, such as the desired heat profile of the heater assembly. As mentioned above, the uniformity of a semiconductor layer deposited on a wafer increases and decreases as the heat profile of the heater assembly becomes more and less uniform.

FIG. 1e is a representative heat/temperature profile along cut line of FIG. 1a of heater assembly 100 with the heater cross sectional embodiment of FIG. 1b showing the variance temperature measured diametrically across heater 160d, 140b, 120, 110, 120, 140a and 160b.

FIG. 1f is a representative heat/temperature profile along cut line of FIG. 1a of heater assembly 100a with the heater cross sectional embodiment of FIG. 1c showing an improved temperature variance measured diametrically across heater 160d, 140b, 120, 110, 120, 140a and 160b as compared to FIG. 1e.

FIG. 1g is a representative heat/temperature profile along cut line of FIG. 1a of heater assembly 100a with the heater cross sectional embodiment optimally designed as discussed below showing an improved temperature variance measured diametrically across heater 160d, 140b, 120, 110, 120, 140a and 160b as compared to FIG. 1f.

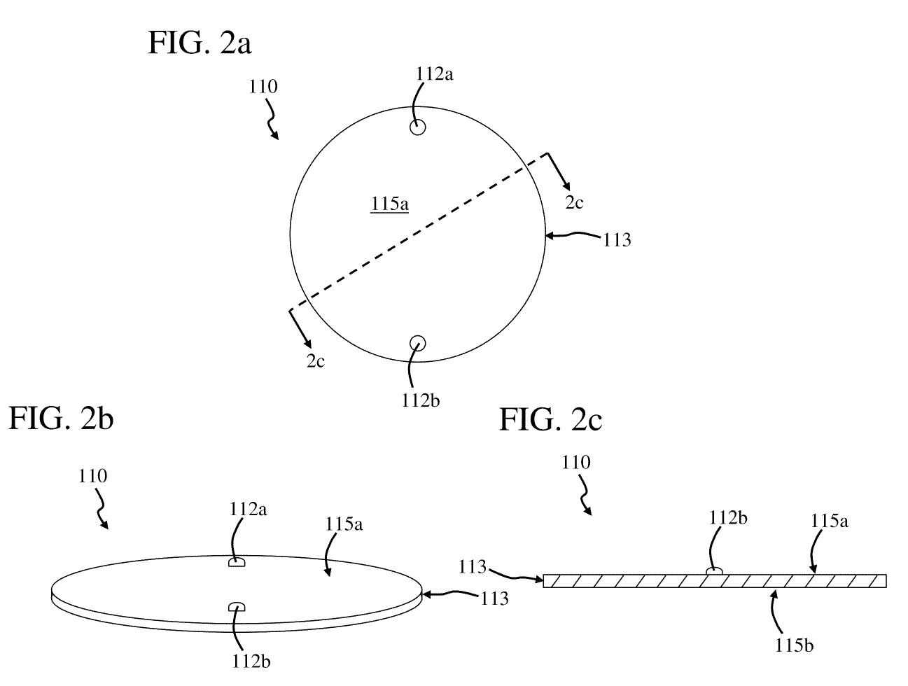

FIG. 2a is a top view of one embodiment of heater plate 110, FIG. 2b is a perspective view of heater plate 110 and FIG. 2c is a cut-away side view of heater plate 110 taken along a cut-line 2c-2c of FIG. 2a. In this embodiment, heater plate sub-assembly 110 includes opposed surfaces 115a and 115b, and is bounded by an outer peripheral surface 113. Outer peripheral surface 113 extends adjacent to inner gap 105 (FIG. 1a), and faces inner segmented heater sub-assembly 120.

In this embodiment, heater plate sub-assembly 110 includes contacts 112a and 112b, which are spaced apart from each other. Heater plate sub-assembly 110 flows heat through opposed surfaces 115a and 115b in response to a potential difference V₀ established between contacts 112a and 112b. Heater plate sub-assembly 110 flows heat through opposed surfaces 115a and 115b in response to a current flowing between contacts 112a and 112b in response to the potential difference established between contacts 112a and 112b from the adjustable signal applied to these contacts as previously discussed.

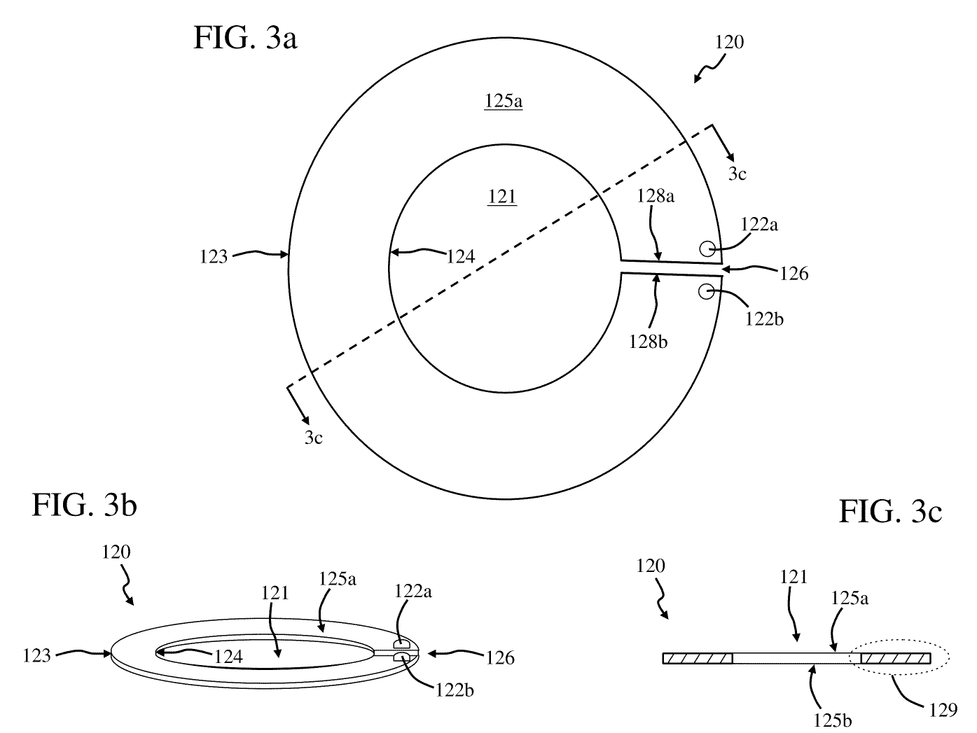

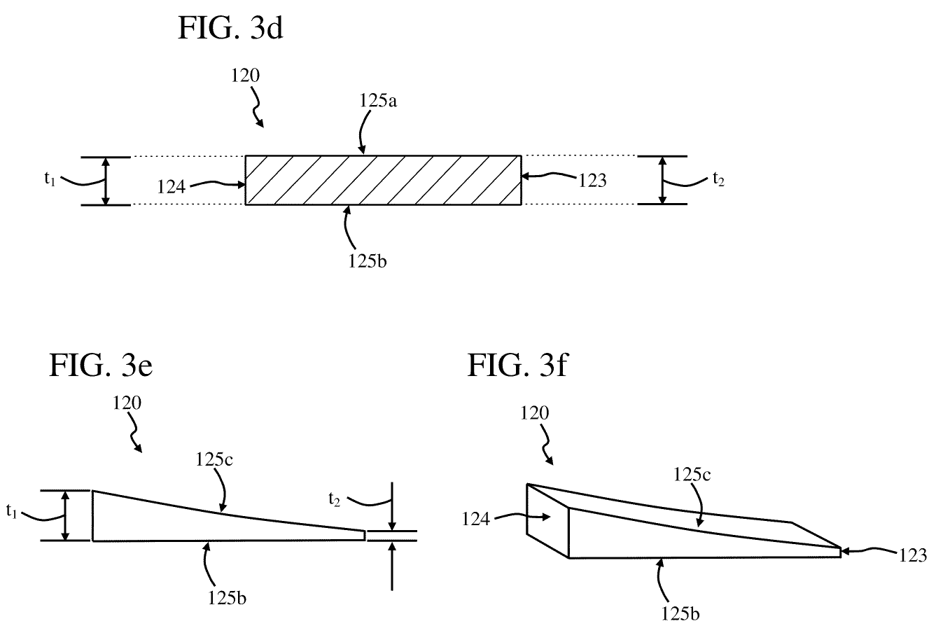

FIG. 3a is a top view of one embodiment of inner segmented heater sub-assembly 120, FIG. 3b is a perspective view of inner segmented heater sub-assembly 120 and FIG. 3c is a cut-away side view of inner segmented heater sub-assembly 120 taken along a cut-line 3c-3c of FIG. 3a. In this embodiment, inner segmented heater sub-assembly 120 includes opposed surfaces 125a and 125b, and is bounded by an outer peripheral surface 123 and inner peripheral surface 124. Opposed surfaces 125a and 125b are gapped surfaces because inner radial slot 126 extends therethrough. Radial slot 126 is dimensioned to inhibit the ability of current to flow between surfaces 128a and 128b.

Outer peripheral surface 123 extends adjacent to intermediate gap 106 (FIGS. 1a and 1b), and faces intermediate segmented heater sub-assembly 140. Inner peripheral surface 124 extends adjacent to inner gap 105 (FIGS. 1a and 1b), and faces inner segmented heater sub-assembly 110. In this way, inner gap 105 is bounded by outer peripheral surface 113 and inner peripheral surface 124. Inner gap 105 is dimensioned to inhibit the ability of current to flow between heater assemblies 110 and 120. Inner segmented heater sub-assembly 120 includes a central opening 121 sized and shaped to receive heater plate sub-assembly 110 (FIGS. 1a and 1b).

In this embodiment, inner segmented heater sub-assembly 120 includes contacts 122a and 122b, which are spaced apart from each other by a radial gap 126. Inner segmented heater sub-assembly 120 flows heat through opposed surfaces 125a and 125b in response to a potential difference established between contacts 122a and 122b. Inner segmented heater sub-assembly 120 flows heat through opposed surfaces 125a and 125b in response to a current flowing between contacts 122a and 122b. It should be noted that the current flows between contacts 122a and 122b in response to the potential difference established between contacts 122a and 122b by the adjustable signal applied as discussed above.

Radial gap 126 is a radial gap because it extends along a radial line 104, which extends radially outward from a center 103 of heater plate sub-assembly 110 (FIG. 1a). It should be noted that, in this embodiment, center 103 of heater plate sub-assembly 110 corresponds to a center of heater assembly 100. In this embodiment, radial gap 126 is bounded by opposed radial gap surfaces 127 and 128. Radial gap surfaces 127 and 128 extend radially outward from center 103 of heater plate sub-assembly 110, and between outer peripheral surface 123 and inner peripheral surface 124.

FIG. 3d is a side view of inner segmented heater sub-assembly 120 in a region 129 of FIG. 3c. As shown in FIG. 3d, inner segmented heater sub-assembly 120 has inner and outer thicknesses t₁ and t₂. Inner thickness t₁ is the thickness of inner segmented heater sub-assembly 120 proximate to inner peripheral surface 124 and outer thickness t₂ is the thickness of inner segmented heater sub-assembly 120 proximate to outer peripheral surface 123.

Inner segmented heater sub-assembly 120 has a uniform thickness when thicknesses t₁ and t₂ are the same, and inner segmented heater sub-assembly 120 has thickness t₁ between outer peripheral surface 123 and inner peripheral surface 124. Inner segmented heater sub-assembly 120 has a uniform thickness when thicknesses t₁ and t₂ are the same, and inner segmented heater sub-assembly 120 has thickness t₂ between outer peripheral surface 123 and inner peripheral surface 124.

Inner segmented heater sub-assembly 120 has a uniform thickness when thicknesses t₁ and t₂ are the same, and opposed surfaces 125a and 125d are spaced apart from each other by thickness t₁. Inner segmented heater sub-assembly 120 has a uniform thickness when thicknesses t₁ and t₂ are the same, and opposed surfaces 125a and 125d are spaced apart from each other by thickness t₂. In the embodiment in which inner segmented heater sub-assembly 120 has a uniform thickness, opposed surfaces 125a and 125b are parallel to each other.

FIG. 3e is a side view of another embodiment of inner segmented heater sub-assembly 120 in region 129, and FIG. 3f is a corresponding perspective view of the embodiment of FIG. 3e, wherein inner segmented heater sub-assembly 120 has a non-uniform thickness. Inner segmented heater sub-assembly 120 of FIGS. 3e and 3f correspond to inner segmented heater sub-assembly 120 of FIG. 1c. In FIGS. 3d and 3e, inner segmented heater sub-assembly 120 has a non-uniform thickness because thicknesses t₁ and t₂ are unequal, and the thickness of inner segmented heater sub-assembly 120 is non-uniform between inner peripheral surface 124 and outer peripheral surface 123. In this particular embodiment, thickness t₁ is greater than thickness t₂. It should be noted, however, that thickness t₂ is greater than thickness t₁ in other embodiments. In the embodiment in which inner segmented heater sub-assembly 120 has a non-uniform thickness, opposed surfaces 125a and 125b are not parallel to each other.

Surfaces 125a and 125b can have many different shapes. For example, in FIG. 3d, surfaces 125a and 125b are flat surfaces which extend parallel to each other because t₁ and t₂ are equal. In FIGS. 3e and 3f, surfaces 125a and 125b are flat surfaces which do not extend parallel to each other because t₁ and t₂ are not equal. In some embodiments, surfaces 125a and 125c are flat surfaces and, in other embodiments, surfaces 125a and 125c are curved surfaces or combinations thereof. In some embodiments, surfaces 125a and 125c are curved so they are concave and, in other embodiments, surfaces 125a and 125c are curved so they are convex.

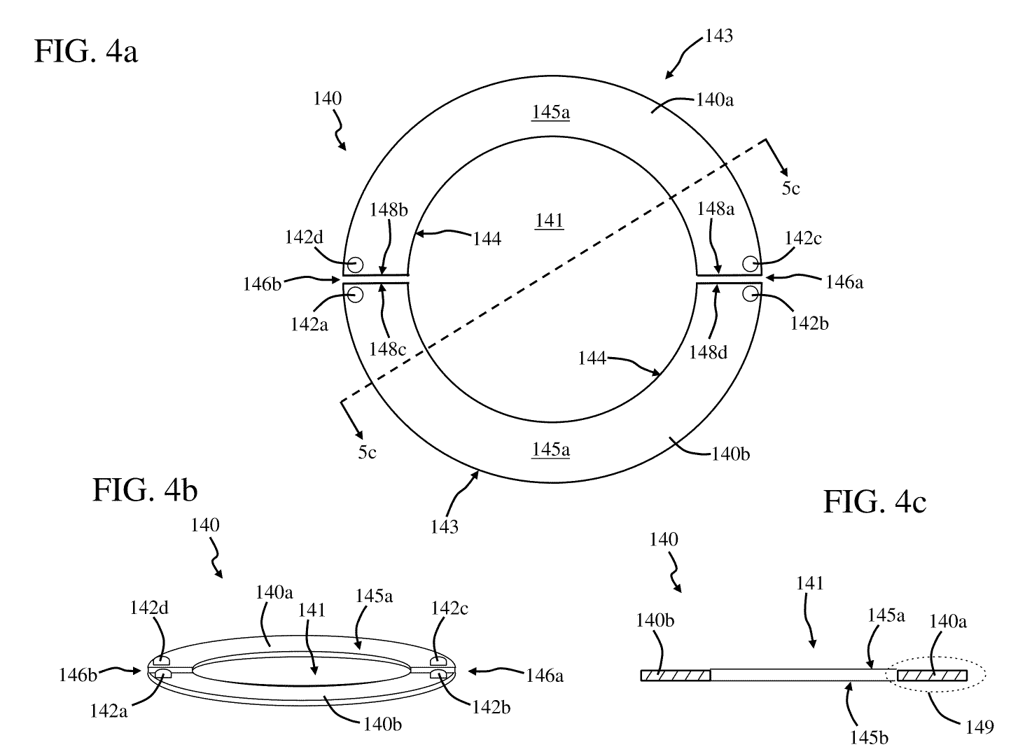

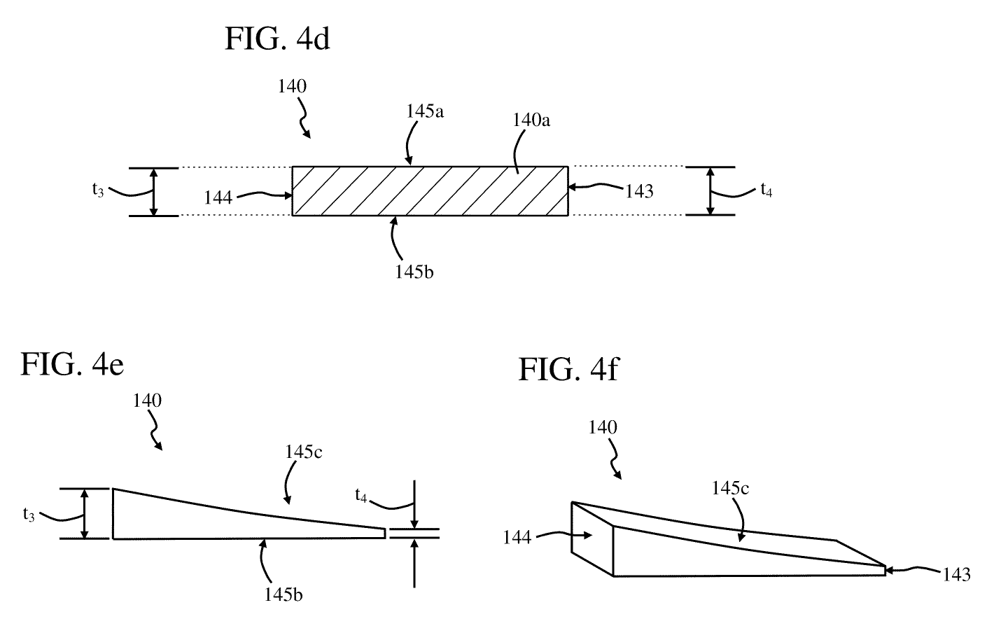

FIG. 4a is a top view of one embodiment of intermediate segmented heater sub-assembly 140, FIG. 4b is a perspective view of intermediate segmented heater sub-assembly 140 and FIG. 4c is a cut-away side view of intermediate segmented heater sub-assembly 140 taken along a cut-line 4c-4c of FIG. 4a. In this embodiment, intermediate segmented heater sub-assembly 140 includes intermediate heater segments 140a and 140b. Intermediate heater segments 140a and 140b include opposed surfaces 145a and 145b, and are bounded by an outer peripheral surface 143 and inner peripheral surface 144. Outer peripheral surface 143 extends adjacent to outer gap 107 (FIGS. 1a and 1b), and faces outer segmented heater sub-assembly 160. Inner peripheral surface 144 extends adjacent to intermediate gap 106 (FIGS. 1a and 1b), and faces inner segmented heater sub-assembly 120. In this way, intermediate gap 106 is bounded by outer peripheral surface 123 and inner peripheral surface 144. Intermediate gap 106 is dimensioned to inhibit the ability of current to flow between heater assemblies 120 and 140. Intermediate segmented heater sub-assembly 140 includes a central opening 141 sized and shaped to receive inner segmented heater sub-assembly 120 (FIGS. 1a and 1b).

In this embodiment, intermediate segmented heater sub-assembly 140 includes contacts 142a and 142b, which are carried by intermediate heater segment 140b. In this embodiment, intermediate segmented heater sub-assembly 140 includes contacts 142c and 142d, which are carried by intermediate heater segment 140a. In this embodiment, contacts 142b and 142c are spaced apart from each other by a radial gap 146a. In this embodiment, contacts 142a and 142d are spaced apart from each other by a radial gap 146b. Intermediate heater segments 140a and 140b are spaced apart from each other by radial gaps 146a and 146b.

Radial gap 146a is a radial gap because it extends along radial line 104, which extends radially outward from center 103 of heater plate sub-assembly 110 (FIG. 1a). In this embodiment, radial gap 146a is bounded by opposed radial gap surfaces 147a and 148a. Radial gap surfaces 147a and 148a extend radially outward from center 103 of heater plate sub-assembly 110, and between outer peripheral surface 143 and inner peripheral surface 144.

Radial gap 146b is a radial gap because it extends along a radial line, which extends radially outward from center 103 of heater plate sub-assembly 110. In this embodiment, radial gap 146b is bounded by opposed radial gap surfaces 147b and 148b. Radial gap surfaces 147b and 148b extend radially outward from center 103 of heater plate sub-assembly 110, and between outer peripheral surface 143 and inner peripheral surface 144. Radial slot 146a is dimensioned to inhibit the ability of current to flow between surfaces 148a and 148d. Radial slot 145b is dimensioned to inhibit the ability of current to flow between surfaces 148b and 148c.

Intermediate segmented heater sub-assembly 140 flows heat through opposed surfaces 145a and 145b in response to a potential difference V₂ and V₃ established between contacts 142a and 142b and between contracts 142c and 142d respectively. It should be noted that the current flows between contacts 142a and 142b in response to the potential difference established between contacts 142a and 142b and between contacts 142c and 142d in response to the potential difference established between contacts 142c and 142d by the adjustable signals applied to the contacts as discussed above.

FIG. 4d is a side view of intermediate segmented heater sub-assembly 140 in a region 149 of FIG. 4c. As shown in FIG. 4d, intermediate segmented heater sub-assembly 140 has inner and outer thicknesses t₃ and t₄. Inner thickness t₃ is the thickness of intermediate segmented heater sub-assembly 140 proximate to inner peripheral surface 144 and outer thickness t₄ is the thickness of intermediate segmented heater sub-assembly 140 proximate to outer peripheral surface 143.

Intermediate segmented heater sub-assembly 140 has a uniform thickness when thicknesses t₃ and t₄ are the same, and intermediate segmented heater sub-assembly 140 has thickness t₃ between outer peripheral surface 143 and inner peripheral surface 144. Intermediate segmented heater sub-assembly 140 has a uniform thickness when thicknesses t₃ and t₄ are the same, and intermediate segmented heater sub-assembly 140 has thickness t₄ between outer peripheral surface 143 and inner peripheral surface 144.

Intermediate segmented heater sub-assembly 140 has a uniform thickness when thicknesses t₃ and t₄ are the same and opposed surfaces 145a and 145d are spaced apart from each other by thickness t₃. Intermediate segmented heater sub-assembly 140 has a uniform thickness when thicknesses t₃ and t₄ are the same, and opposed surfaces 145a and 145d are spaced apart from each other by thickness t₄. In the embodiment in which intermediate segmented heater sub-assembly 140 has a uniform thickness, opposed surfaces 145a and 145b are parallel to each other. It should be noted that intermediate heater segments 140a and 140b have uniform thicknesses when intermediate segmented heater sub-assembly 140 has a uniform thickness.

FIG. 4e is a side view of another embodiment of intermediate segmented heater sub-assembly 140 in region 149, and FIG. 4f is a corresponding perspective view of the embodiment of FIG. 4e, wherein intermediate segmented heater sub-assembly 140 has a non-uniform thickness. Intermediate segmented heater sub-assembly 140 of FIGS. 4e and 4f correspond to intermediate segmented heater sub-assembly 140 of FIG. 1c. In FIGS. 4d and 4e, intermediate segmented heater sub-assembly 140 has a non-uniform thickness because thicknesses t₃ and t₄ are unequal, and the thickness of intermediate segmented heater sub-assembly 140 is non-uniform between inner peripheral surface 144 and outer peripheral surface 143. In this particular embodiment, thickness t₃ is greater than thickness t₄. It should be noted, however, that thickness t₄ is greater than thickness t₃ in other embodiments. In the embodiment in which intermediate segmented heater sub-assembly 140 has a non-uniform thickness, opposed surfaces 145a and 145b are not parallel to each other.

Surfaces 145a and 145b can have many different shapes. For example, in FIG. 4d, surfaces 145a and 145b are flat surfaces which extend parallel to each other because t₃ and t₄ are equal. In FIGS. 4e and 4f, surfaces 145a and 145b are flat surfaces which do not extend parallel to each other because t₃ and t₄ are not equal. In some embodiments, surfaces 145a and 145c are flat surfaces and, in other embodiments, surfaces 145a and 145c are curved surfaces or combinations thereof. In some embodiments, surfaces 145a and 145c are curved so they are concave and, in other embodiments, surfaces 145a and 145c are curved so they are convex.

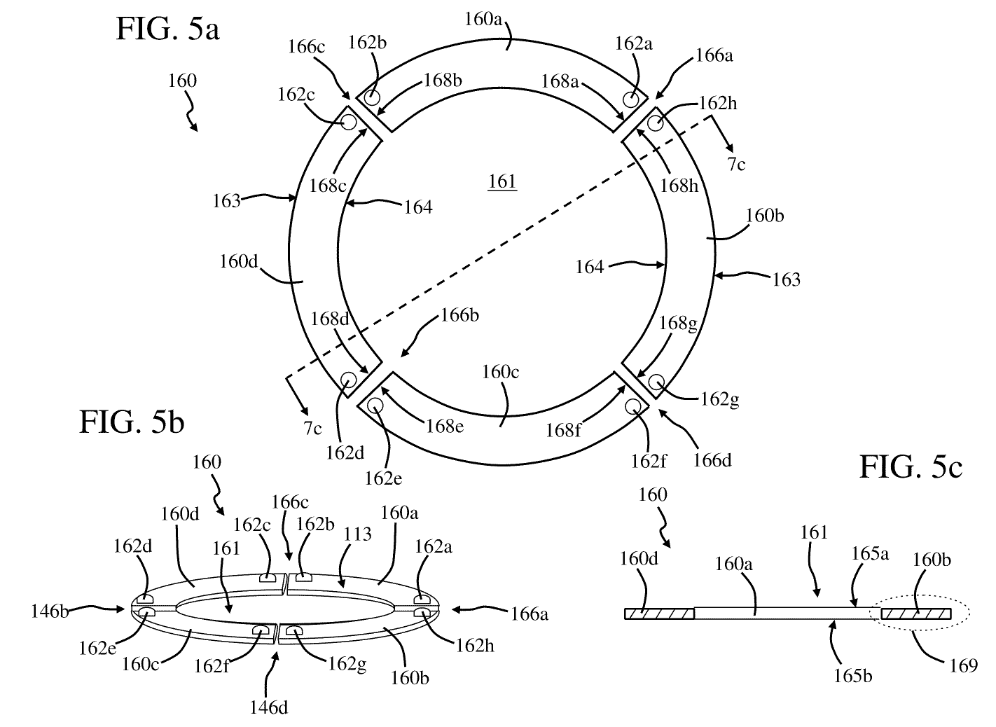

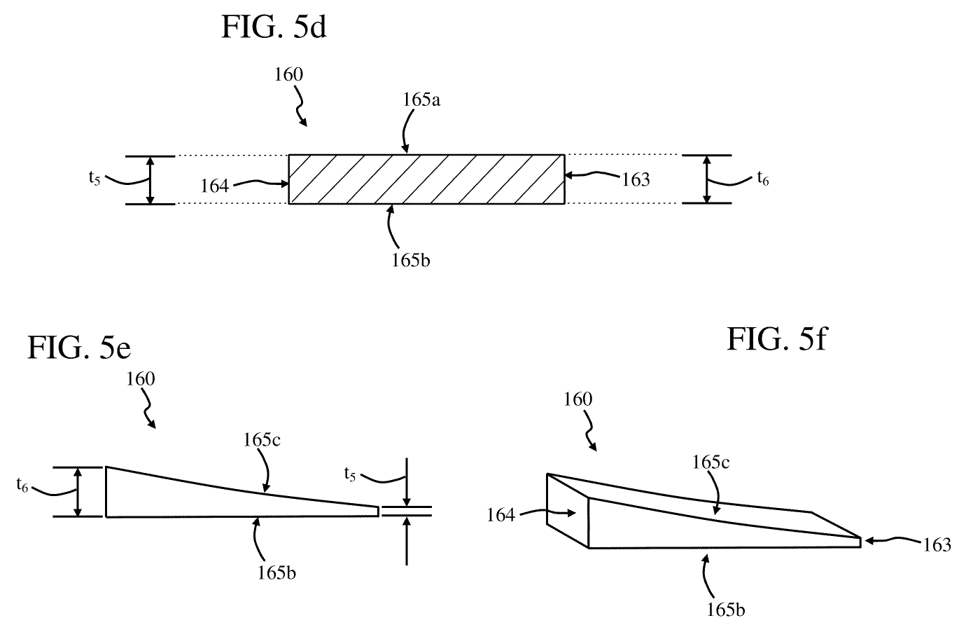

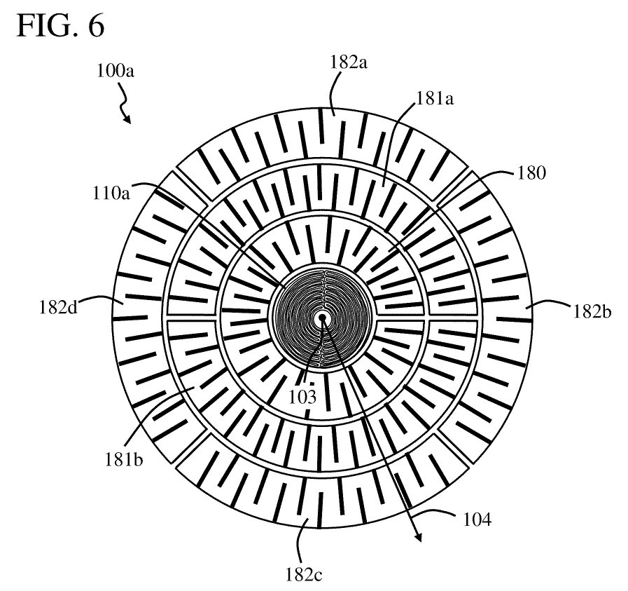

FIG. 5a is a top view of one embodiment of outer segmented heater sub-assembly 160, FIG. 5b is a perspective view of outer segmented heater sub-assembly 160 and FIG. 5c is a cut-away side view of outer segmented heater sub-assembly 160 taken along a cut-line 5c-5c of FIG. 5a. In this embodiment, outer segmented heater sub-assembly 160 includes outer heater segments 160a, 160b, 160c and 160d. Outer heater segments 160a, 160b, 160c and 160d include opposed surfaces 165a and 165b, and are bounded by an outer peripheral surface 163 and inner peripheral surface 164. Outer peripheral surface 163 extends adjacent to the outer periphery of heater assembly 100 (FIGS. 1a and 1b), and faces the outer periphery of heater assembly 100. Inner peripheral surface 164 extends adjacent to outer gap 107 (FIGS. 1a and 1b), and faces intermediate segmented heater sub-assembly 140. In this way, outer gap 107 is bounded by outer peripheral surface 143 and inner peripheral surface 163. Outer gap 107 is dimensioned to inhibit the ability of current to flow between heater assemblies 140 and 160. Outer segmented heater sub-assembly 160 includes a central opening 161 sized and shaped to receive intermediate segmented heater sub-assembly 140 (FIGS. 1a and 1b).

In this embodiment, outer segmented heater assembly includes contacts 162a and 162b, which are carried by intermediate heater segment 160a. In this embodiment, outer segmented heater sub-assembly 160 includes contacts 162c and 162d, which are carried by intermediate heater segment 160d. In this embodiment, outer segmented heater sub-assembly 160 includes contacts 162e and 162f, which are carried by intermediate heater segment 160c. In this embodiment, outer segmented heater sub-assembly 160 includes contacts 162g and 162h, which are carried by intermediate heater segment 160b.

In this embodiment, contacts 162a and 162h are spaced apart from each other by a radial gap 166a. Further, outer heater segments 160a and 160b are spaced apart from each other by radial gap 166a. In this embodiment, contacts 162b and 162c are spaced apart from each other by a radial gap 166c. Further, outer heater segments 160a and 160d are spaced apart from each other by radial gap 166c. In this embodiment, contacts 162d and 162e are spaced apart from each other by a radial gap 166b. Further, outer heater segments 160c and 160d are spaced apart from each other by radial gap 166b. In this embodiment, contacts 162f and 162g are spaced apart from each other by a radial gap 166d. Further, outer heater segments 160b and 160c are spaced apart from each other by radial gap 166d.

Radial gap 166a is a radial gap because it extends along a radial line, which extends radially outward from center 103 of heater plate sub-assembly 110. In this embodiment, radial gap 166a is bounded by opposed radial gap surfaces 168a and 168h. Radial gap surfaces 168a and 168h extend radially outward from center 103 of heater plate sub-assembly 110, and between outer peripheral surface 163 and inner peripheral surface 164.

Radial gap 166b is a radial gap because it extends along a radial line, which extends radially outward from center 103 of heater plate sub-assembly 110. In this embodiment, radial gap 166b is bounded by opposed radial gap surfaces 168d and 168e. Radial gap surfaces 168d and 168e extend radially outward from center 103 of heater plate sub-assembly 110, and between outer peripheral surface 163 and inner peripheral surface 164.

Radial gap 166c is a radial gap because it extends along a radial line, which extends radially outward from center 103 of heater plate sub-assembly 110. In this embodiment, radial gap 166c is bounded by opposed radial gap surfaces 168b and 168c. Radial gap surfaces 168b and 168c extend radially outward from center 103 of heater plate sub-assembly 110, and between outer peripheral surface 163 and inner peripheral surface 164.

Radial gap 166d is a radial gap because it extends along a radial line, which extends radially outward from center 103 of heater plate sub-assembly 110. In this embodiment, radial gap 166d is bounded by opposed radial gap surfaces 168f and 168g. Radial gap surfaces 168f and 168g extend radially outward from center 103 of heater plate sub-assembly 110, and between outer peripheral surface 163 and inner peripheral surface 164.

Radial slot 166a is dimensioned to inhibit the ability of current to flow between surfaces 168a and 168h. Radial slot 166b is dimensioned to inhibit the ability of current to flow between surfaces 168d and 168e. Radial slot 166c is dimensioned to inhibit the ability of current to flow between surfaces 168b and 168c. Radial slot 166d is dimensioned to inhibit the ability of current to flow between surfaces 168f and 168g.

Outer segmented heater sub-assembly 160 flows heat through opposed surfaces 165a and 165b in response to a potential difference V₄, V₅, V₆, and V₇ established between contacts 162a and 162b, between contracts 162c and 162d, between contacts 162e and 162f, between contracts 162g and 162h respectively. It should be noted that the current flows between contacts 162a and 162b in response to the potential difference established between contacts 162a and 162b and between contacts 162c and 162d in response to the potential difference established between contacts 162c and 162d, and between contacts 162e and 162f in response to the potential established between contacts 162e and 162f and between contacts 162g and 162h in response to the potential established between contacts 162g and 162h by the adjustable signals applied to the contacts as discussed above.

FIG. 5d is a side view of outer segmented heater sub-assembly 160 in a region 169 of FIG. 5c. As shown in FIG. 5d, outer segmented heater sub-assembly 160 has inner and outer thicknesses t₅ and t₆. Inner thickness t₅ is the thickness of outer segmented heater sub-assembly 160 proximate to inner peripheral surface 164 and outer thickness t₆ is the thickness of outer segmented heater sub-assembly 160 proximate to outer peripheral surface 163.

Outer segmented heater sub-assembly 160 has a uniform thickness when thicknesses t₅ and t₆ are the same, and outer segmented heater sub-assembly 160 has thickness t₅ between outer peripheral surface 163 and inner peripheral surface 164. Outer segmented heater sub-assembly 160 has a uniform thickness when thicknesses t₅ and t₆ are the same, and outer segmented heater sub-assembly 160 has thickness t₆ between outer peripheral surface 163 and inner peripheral surface 164.

Outer segmented heater sub-assembly 160 has a uniform thickness when thicknesses t₅ and t₆ are the same, and opposed surfaces 165a and 165b are spaced apart from each other by thickness t₅. Outer segmented heater sub-assembly 160 has a uniform thickness when thicknesses t₅ and t₆ are the same, and opposed surfaces 165a and 165b are spaced apart from each other by thickness t₆. In the embodiment in which outer segmented heater sub-assembly 160 has a uniform thickness, opposed surfaces 165a and 165b are parallel to each other. It should be noted that outer heater segments 160a, 160b, 160c and 160d have uniform thicknesses when outer segmented heater sub-assembly 160 has a uniform thickness.

FIG. 5e is a side view of another embodiment of outer segmented heater sub-assembly 160 in region 169, and FIG. 5f is a corresponding perspective view of the embodiment of FIG. 5e, wherein outer segmented heater sub-assembly 160 has a non-uniform thickness. Outer segmented heater sub-assembly 160 of FIGS. 5e and 5f correspond to outer segmented heater sub-assembly 160 of FIG. 1c. In FIGS. 5d and 5e, outer segmented heater sub-assembly 160 has a non-uniform thickness because thicknesses t₅ and t₆ are unequal, and the thickness of outer segmented heater sub-assembly 160 is non-uniform between inner peripheral surface 164 and outer peripheral surface 163. In this particular embodiment, thickness t₅ is greater than thickness t₆. It should be noted, however, that thickness t₆ is greater than thickness t₅ in other embodiments. In the embodiment in which outer segmented heater sub-assembly 160 has a non-uniform thickness, opposed surfaces 165a and 165b are not parallel to each other.

Surfaces 165a and 165b can have many different shapes. For example, in FIG. 5d, surfaces 165a and 165b are flat surfaces which extend parallel to each other because t₅ and t₆ are equal. In FIGS. 5e and 5f, surfaces 165a and 165b do not extend parallel to each other because t₅ and t₆ are not equal. In some embodiments, surfaces 165a and 165c are flat surfaces and, in other embodiments, surfaces 165a and 165c are curved surfaces. In some embodiments, surfaces 165a and 165c are curved so they are concave and, in other embodiments, surfaces 165a and 165c are curved so they are convex.

FIG. 6 is a top view of one embodiment of a heater assembly 100a. As will be discussed in more detail below, heater assembly 100a can be used to heat a wafer. It is desirable to heat the wafer(s) in many different situations, such as when depositing a material thereon. Heater assembly 100a can be used in a deposition system to heat the wafer. The wafer is heated to facilitate the ability to deposit material thereon. The material can be of many different types, such as semiconductor material.

In this embodiment, heater assembly 100a includes a coiled heater 110a, and an inner slotted heater ring 180 spaced from coiled heater sub-assembly 110a by inner gap 105. Heater assembly 100a includes intermediate slotted heater sub-assemblies 181a and 181b spaced from slotted inner heater sub-assembly 180 by intermediate gap 106. Heater assembly 100a includes outer slotted heater sub-assemblies 182a, 182b, 183c and 184d spaced from slotted intermediate heater sub-assemblies 181a and 181b by outer gap 107. It should be noted that inner gap 105, intermediate gap 106 and outer gap 107 are annular gaps because they extend annularly around coiled heater sub-assembly 110a, inner slotted ring heater sub-assemblies 180, intermediate slotted heaters sub-assemblies 181a and 181b and outer slotted heater sub-assemblies 182a, 182b, 183c and 184d respectively.

Heater sub-assemblies 110a, 180, 181a and 181b and 182a, 182b, 183c and 184d can be constructed in many different ways, several of which will be discussed in more detail below.

It should also be noted that heater assembly 100a, as shown in FIG. 6, has a uniform thickness. Heater assembly 100 of FIG. 6 has a uniform thickness because the thicknesses of heaters 110a, 180, 181a and 181b and 182a, 182b, 183c and 184d have the same thickness values between inner gap 105 and the outer periphery of heaters 182a, 182b, 183c and 184d.

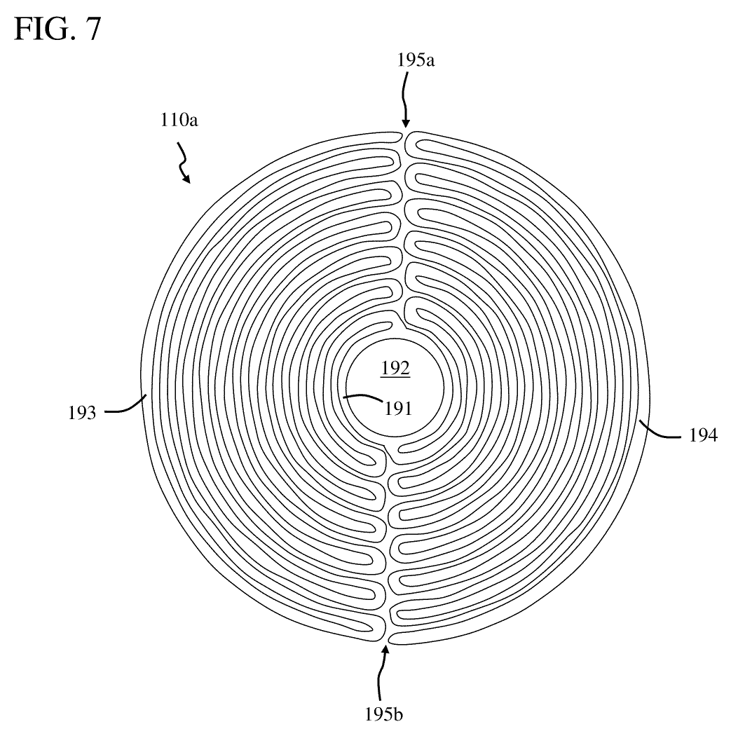

FIG. 7 is a top view of one embodiment of coiled heater 110a. In this embodiment, coiled heater 110a includes an inner ring 191 having a central opening 192. In this embodiment, coiled heater 110a includes coils 193 and 194 which are connected to opposed sides of inner ring 191. Inner coils 193 and 194 are spaced apart from each other by gaps 195a and 195b, wherein gaps 195a and 195b extend between inner coils 193 and 194 and coil ring 191.

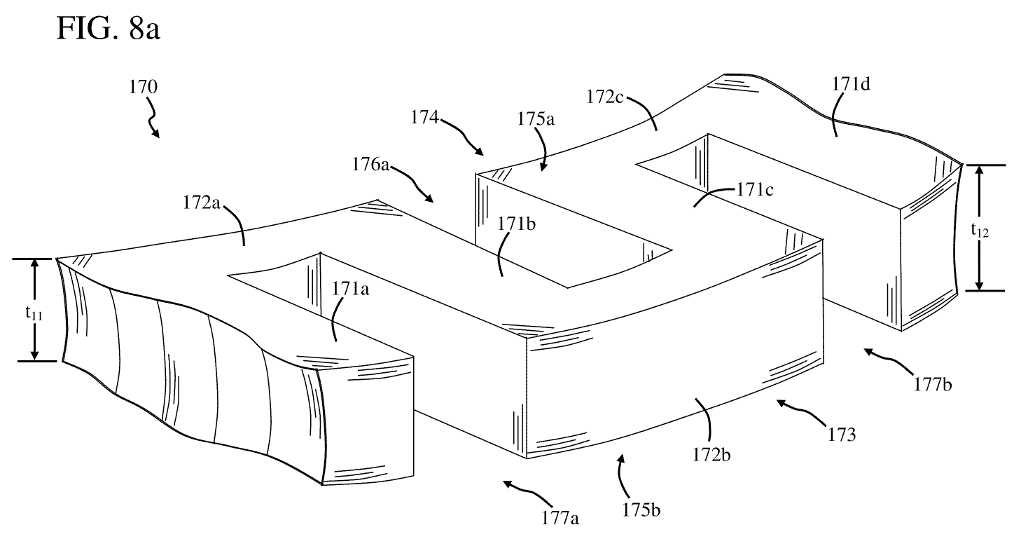

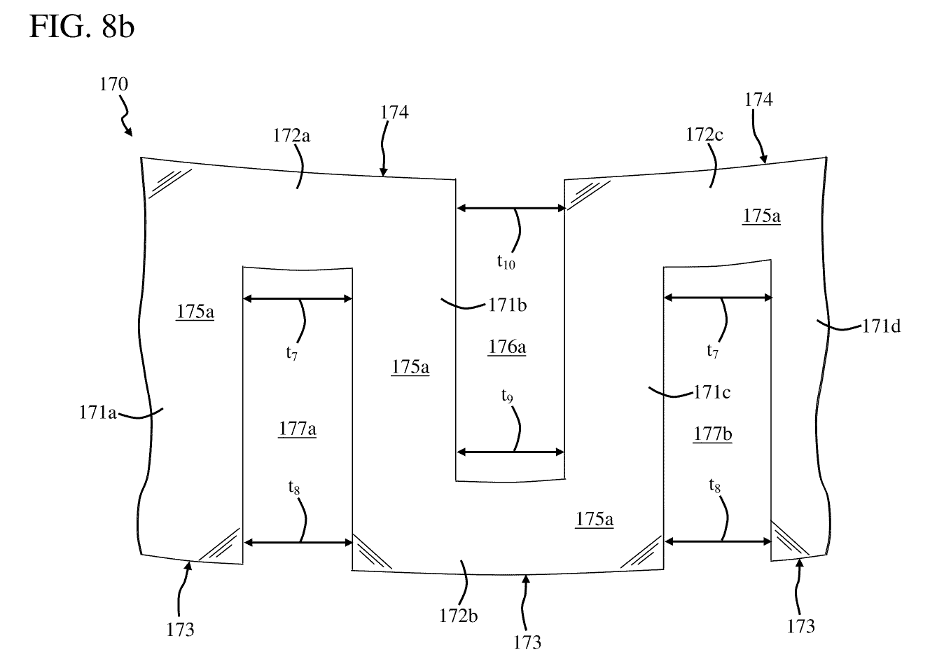

FIGS. 8a and 8b are perspective and top views, respectively, of heater coil 170 of one embodiment of a heater. It should be noted that heater coil 170 can be included in a heater assembly, such as the heater assemblies discussed herein. For example, heater coil 170 can be included in heater assemblies 100 and 100a. Heater coil 170 can be included in a heater assembly in many different ways. In some embodiments, heater coil 170 is included in an inner segmented heater 180 in FIG. 6. In some embodiments, heater coil 170 is included in intermediate segmented heater 181a and 181b. In some embodiments, heater coil 170 is included in outer segmented heater 182a, 182b, 182c and 182d. Several of these embodiments will be discussed in more detail below.

In FIGS. 8a and 8b, heater coil 170 includes a plurality of inner and outer radial slots, wherein the inner radial slot faces an inner peripheral surface and the outer radial slot faces an outer peripheral surface. The inner and outer radial slots are radial gaps because they are lengthened along a radial line, such as radial line 104 of FIGS. 1a and 6, which extends radially outward from a center, such as center 103. Further, the inner and outer radial slots are radial gaps because they are shortened transversely to the radial line.

In this embodiment, heater coil 170 includes an inner radial slot 176a, which faces inner peripheral surface 174. Inner radial slot 176a is a radial gap because it extends along a radial line, such as radial line 104 of FIGS. 1a and 6. Inner radial slot 176a is bounded by a transverse coil segment 172b and opposed radial segment 171b and 171c. Transverse segment 172b is a transverse segment because it extends transversely to the radial line, such as radial line 104 of FIGS. 1a and 6. Radial coil segments 171b and 171c are radial segments because they extend along the radial line, such as radial line 104 of FIGS. 1a and 6.

It should be noted that a radial coil segment is lengthened in the radial direction and shortened in the transverse direction. The radial coil segment is lengthened in the radial direction and shorted in the transverse direction because the radial coil segment is longer in the radial direction and shorter in the transverse direction.

Further, a transverse coil segment is shortened in the radial direction and lengthened in the transverse direction. The transverse coil segment is shortened in the radial direction and lengthened in the transverse direction because the transverse coil segment is shorter in the radial direction and longer in the transverse direction.

In this embodiment, heater coil 170 includes outer radial slots 177a and 177b, which face outer peripheral surface 173. Outer radial slot 177a is a radial gap because it extends along a radial line, such as radial line 104 of FIGS. 1a and 6. Outer radial slot 177a is bounded by a transverse coil segment 172a and opposed radial coil segments 171a and 171b. Transverse coil segment 172a is a transverse coil segment because it extends along the radial line, such as radial line 104 of FIGS. 1a and 6. Radial coil segments 171a and 171b are radial coil segments because they extend along the radial line, such as radial line 104 of FIGS. 1a and 6.

Outer radial slot 177b is a radial gap because it extends along a radial line, such as radial line 104 of FIGS. 1a and 6. Outer radial slot 177b is bounded by a transverse coil segment 172c and opposed radial coil segments 171c and 171d. Transverse coil segment 172c is a transverse coil segment because it extends along the radial line, such as radial line 104 of FIGS. 1a and 6. Radial coil segments 171c and 171d are radial coil segments because they extend along the radial line, such as radial line 104 of FIGS. 1a and 6.

FIG. 8b shows that radial coil segments 171a and 171b are spaced apart from each other by a distance t₇ proximate to inner peripheral surface 174. Further, radial coil segments 171a and 171b are spaced apart from each other by a distance t₈ proximate to outer peripheral surface 173. In one embodiment, distance t₇ is less than distance t₈. In another embodiment distance t₇ is the same as distance t₈. In another embodiment distance t₇ is greater than as distance t₈.

In this embodiment, radial coil segments 171b and 171c are spaced apart from each other by a distance t₉ proximate to outer peripheral surface 173, as shown in FIG. 8b. Further, radial coil segments 171b and 171c are spaced apart from each other by a distance t₁₀ proximate to inner peripheral surface 174. In this embodiment, distance t₁₀ is less than distance t₉. In another embodiment distance t₁₀ is the same as distance t₉. In another embodiment distance t₁₀ is greater than as distance t₉.

In this embodiment, radial coil segments 171c and 171d are spaced apart from each other by distance t₇ proximate to inner peripheral surface 174, as shown in FIG. 8b. Further, radial coil segments 171c and 171d are spaced apart from each other by a distance t₈ proximate to outer peripheral surface 173. In this embodiment, distance t₇ is less than distance t₈. In another embodiment distance t₇ is the same as distance t₈. In another embodiment distance t₇ is greater than as distance t₈.

As mentioned above, a heater assembly has a uniform thickness in some embodiments, and a non-uniform thickness in other embodiments. Examples of heater assemblies having uniform and non-uniform thicknesses are shown in FIGS. 1b and 1c. In FIGS. 8a and 8b, heater coil 170 has a uniform thickness because the thicknesses of heater coil 170 proximate to and between outer peripheral surface 173 and inner peripheral surface 174 are the same. For example, in this embodiment, heater coil 170 has a thickness t₁₁ proximate to inner peripheral surface 174 and a thickness t₁₂ proximate to outer peripheral surface 173, wherein thicknesses t₁₁ and t₁₂ are the same. In this embodiment, the thickness of heater coil 170 between outer peripheral surface 173 and inner peripheral surface 174 is thickness t₁₁. Further, the thickness of heater coil 170 between outer peripheral surface 173 and inner peripheral surface 174 is thickness t₁₂. In this way, heater coil 170 has a uniform thickness. An example of a heater coil with a non-uniform thickness will be discussed in more detail presently.

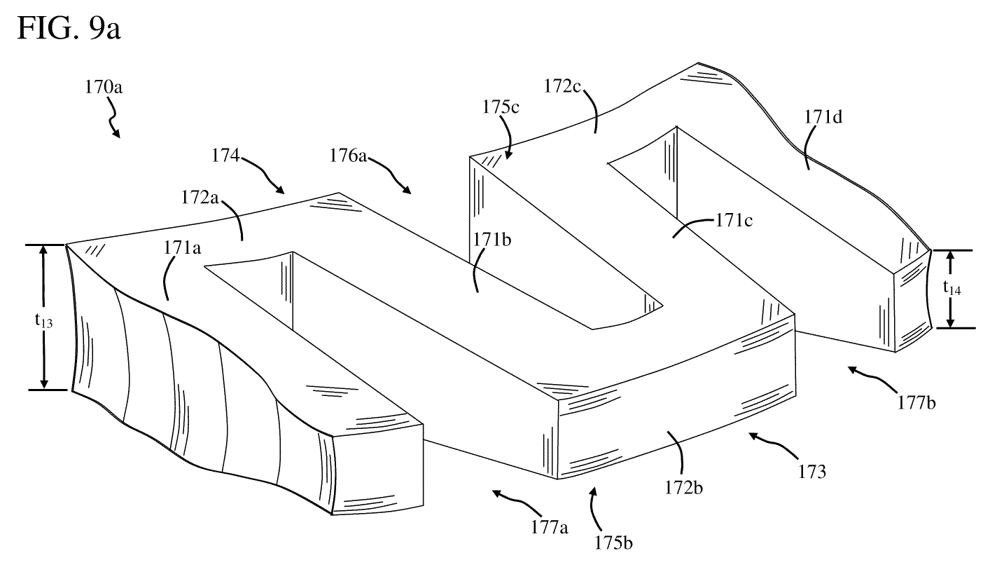

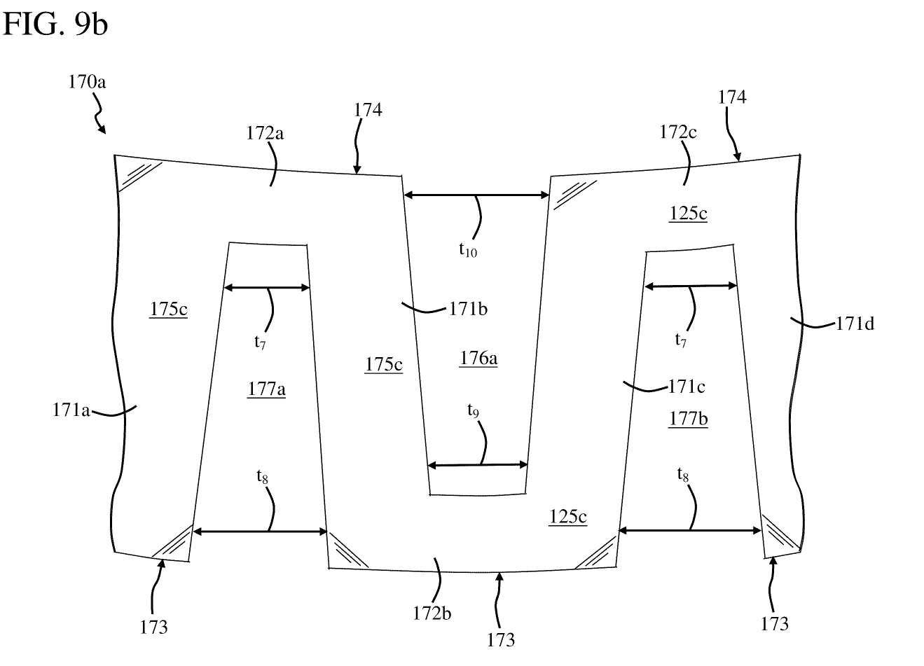

FIGS. 9a and 9b are perspective and top views, respectively, of another embodiment of a heater coil, denoted as heater coil 170a. It should be noted that heater coil 170a can be included in a heater assembly, such as the heater assemblies discussed herein. For example, heater coil 170a can be included in an inner segmented heater 181 in FIG. 6. In some embodiments, heater coil 170 is included in intermediate segmented heater 181a and 181b. In some embodiments, heater coil 170 is included in outer segmented heater 182a, 182b, 182c and 182d. Several of these embodiments will be discussed in more detail below.

In FIGS. 9a and 9b, heater coil 170a includes a plurality of inner and outer radial slots, wherein the inner radial slot faces an inner peripheral surface and the outer radial slot faces an outer peripheral surface. As mentioned above, the inner and outer radial slots are radial gaps because they are lengthened along a radial line, such as radial line 104 of FIGS. 1a and 6, which extends radially outward from a center, such as center 103, of the heater assembly. Further, the inner and outer radial slots are radial gaps because they are shortened transversely to the radial line.

In this embodiment, heater coil 170a includes inner radial slot 176a, which faces inner peripheral surface 174. As mentioned above, inner radial slot 176a is a radial gap because it extends along a radial line, such as radial line 104 of FIGS. 1a and 6. Inner radial slot 176a is bounded by a transverse coil segment 172b and opposed radial coil segments 171b and 171c. Transverse coil segment 172b is a transverse coil segment because it extends transversely to the radial line, such as radial line 104 of FIGS. 1a and 6. Radial coil segments 171b and 171c are radial coil segments because they extend along the radial line, such as radial line 104 of FIGS. 1a and 6.

As mentioned above, a radial coil segment is lengthened in the radial direction and shortened in the transverse direction. The radial coil segment is lengthened in the radial direction and shorted in the transverse direction because the radial coil segment is longer in the radial direction and shorter in the transverse direction.

Further, a transverse coil segment is shortened in the radial direction and lengthened in the transverse direction. The transverse coil segment is shortened in the radial direction and lengthened in the transverse direction because the transverse coil segment is shorter in the radial direction and longer in the transverse direction.

In this embodiment, heater coil 170a includes outer radial slots 177a and 177b, which face outer peripheral surface 173. As mentioned above, outer radial slot 177a is a radial gap because it extends along a radial line, such as radial line 104 of FIGS. 1a and 6. Outer radial slot 177a is bounded by a transverse coil segment 172a and opposed radial coil segments 171a and 171b. Transverse coil segment 172a is a transverse coil segment because it extends along the radial line, such as radial line 104 of FIGS. 1a and 6. Radial coil segments 171a and 171b are radial coil segments because they extend along the radial line, such as radial line 104 of FIGS. 1a and 6.

As mentioned above, outer radial slot 177b is a radial gap because it extends along a radial line, such as radial line 104 of FIGS. 1a and 6. Outer radial slot 177b is bounded by a transverse coil segment 172c and opposed radial coil segments 171c and 171d. Transverse coil segment 172c is a transverse coil segment because it extends along the radial line, such as radial line 104 of FIGS. 1a and 6. Radial coil segments 171c and 171d are radial coil segments because they extend along the radial line, such as radial line 104 of FIGS. 1a and 6.

As mentioned above, radial coil segments 171a and 171b are spaced apart from each other by a distance t₇ proximate to inner peripheral surface 174, as shown in FIG. 9b. Further, radial coil segments 171a and 171b are spaced apart from each other by a distance t₈ proximate to outer peripheral surface 173. In this embodiment, distance t₇ is less than distance t₈. In another embodiment distance t₇ is the same as distance t₈. In another embodiment distance t₇ is greater than as distance t₈.

As mentioned above, radial coil segments 171b and 171c are spaced apart from each other by a distance t₉ proximate to outer peripheral surface 173, as shown in FIG. 9b. Further, radial coil segments 171b and 171c are spaced apart from each other by a distance t₁₀ proximate to inner peripheral surface 174. In this embodiment, distance t₁₀ is less than distance t₉. In another embodiment distance t₁₀ is the same as distance t₉. In another embodiment distance t₁₀ is greater than as distance t₉.

As mentioned above, radial coil segments 171c and 171d are spaced apart from each other by distance t₇ proximate to inner peripheral surface 174, as shown in FIG. 9b. Further, radial coil segments 171c and 171d are spaced apart from each other by a distance t₈ proximate to outer peripheral surface 173. In this embodiment, distance t₇ is less than distance t₈. In another embodiment distance t₇ is the same as distance t₈. In another embodiment distance t₇ is greater than distance t₈.

As mentioned above, a heater assembly has a uniform thickness in some embodiments, and a non-uniform thickness in other embodiments. Examples of heater assemblies having uniform and non-uniform thicknesses are shown in FIGS. 1b and 1c. In FIGS. 8a and 8b, heater coil 170 has a uniform thickness. In FIGS. 9a and 9b, however, heater coil 170a has a non-uniform thickness.

Heater coil 170a has a non-uniform thickness because the thicknesses of heater coil 170 proximate to and between outer peripheral surface 173 and inner peripheral surface 174 are not the same. For example, in this embodiment, heater coil 170 has a thickness t₁₃ proximate to inner peripheral surface 174 and a thickness t₁₄ proximate to outer peripheral surface 173, wherein thicknesses t₁₃ and t₁₄ are not the same. In this embodiment, the thickness of heater coil 170 between outer peripheral surface 173 and inner peripheral surface 174 is not thickness t₁₃. Further, the thickness of heater coil 170 between outer peripheral surface 173 and inner peripheral surface 174 is not thickness t₁₃. In this way, heater coil 170 has a non-uniform thickness.

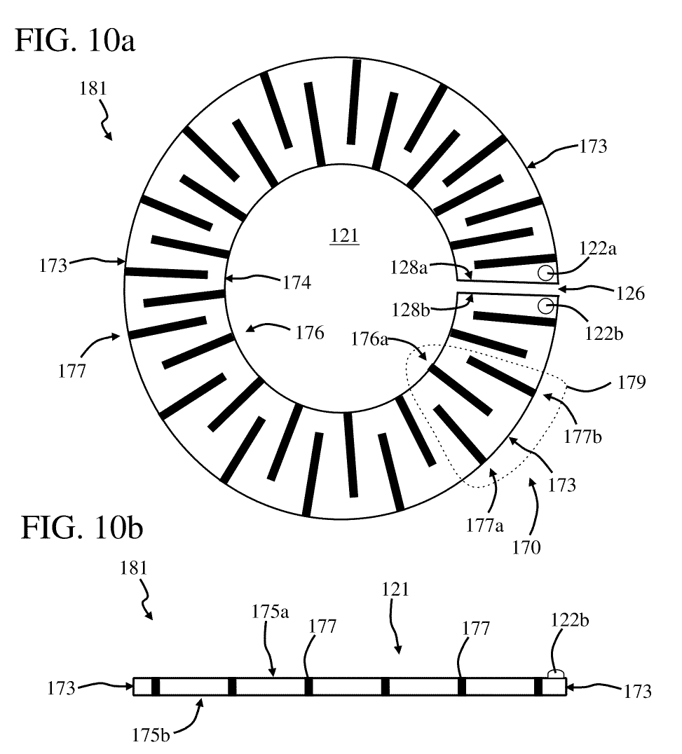

FIGS. 10a and 10b are top and side views, respectively, of one embodiment of a coiled inner segmented heater assembly 181. Coiled inner segmented heater assembly 181 is a coiled heater assembly because it includes a heater coil. In this embodiment, coiled inner segmented heater assembly 181 includes heater coil 170 of FIGS. 8a and 8b, as indicated in a region 179 of FIG. 10a. However, in some embodiments, coiled inner segmented heater assembly 181 includes heater coil 170a of FIGS. 9a and 9b. In this way, coiled inner segmented heater assembly 181 is a coiled heater assembly.

In this embodiment, coiled inner segmented heater assembly 181 includes opposed gapped surfaces 175a and 175b, and is bounded by outer peripheral gapped surface 173 and inner peripheral gapped surface 174. Outer peripheral gapped surface 173 extends adjacent to intermediate gap 106 (FIG. 6), and inner peripheral gapped surface 174 extends adjacent to inner gap 105 (FIG. 6). In this way, inner gap 105 is bounded by outer peripheral surface 113 and inner peripheral gapped surface 174. Inner gap 105 is dimensioned to inhibit the ability of current to flow between heater assemblies 180 and 181. Inner segmented heater assembly 181 includes central opening 121, which is sized and shaped to receive coiled heater plate 180 (FIGS. 6 and 7).

Opposed gapped surfaces 175a and 175b are gapped surfaces because inner radial slot 176 extends therethrough. Opposed gapped surfaces 175a and 175b are gapped surfaces because outer radial slot 177 extends therethrough. Outer peripheral gapped surface 173 and inner peripheral gapped surface 174 are gapped surfaces because inner radial slot 176 extends therethrough. Outer peripheral gapped surface 173 and inner peripheral gapped surface 174 are gapped surfaces because outer radial slot 177 extends therethrough. Examples of surfaces that are not gapped surfaces are discussed in more detail above.

In this embodiment, coiled inner segmented heater assembly 181 includes contacts 172a and 172b, which are spaced apart from each other by a radial gap 176. Coiled inner segmented heater assembly 181 flows heat through opposed surfaces 145a and 145b in response to a potential difference V₁ established between contacts 172a and 172b. Coiled inner segmented heater assembly 181 flows heat through opposed surfaces 175a and 175b in response to a current flowing between contacts 172a and 172b. It should be noted that the current flows between contacts 172a and 172b in response to the potential difference established between contacts 172a and 172b.

Radial gap 126 is a radial gap because it extends along a radial line 104, which extends radially outward from a center 103 of heater plate sub-assembly 110 (FIG. 1a). It should be noted that, in this embodiment, center 103 of heater plate sub-assembly 110 corresponds to a center of heater assembly 100. In this embodiment, radial gap 126 is bounded by opposed radial gap surfaces 128a and 128b. Radial gap surfaces 128a and 128b extend radially outward from center 103 of heater plate sub-assembly 110, and between outer peripheral gapped surface 173 and inner peripheral gapped surface 174.

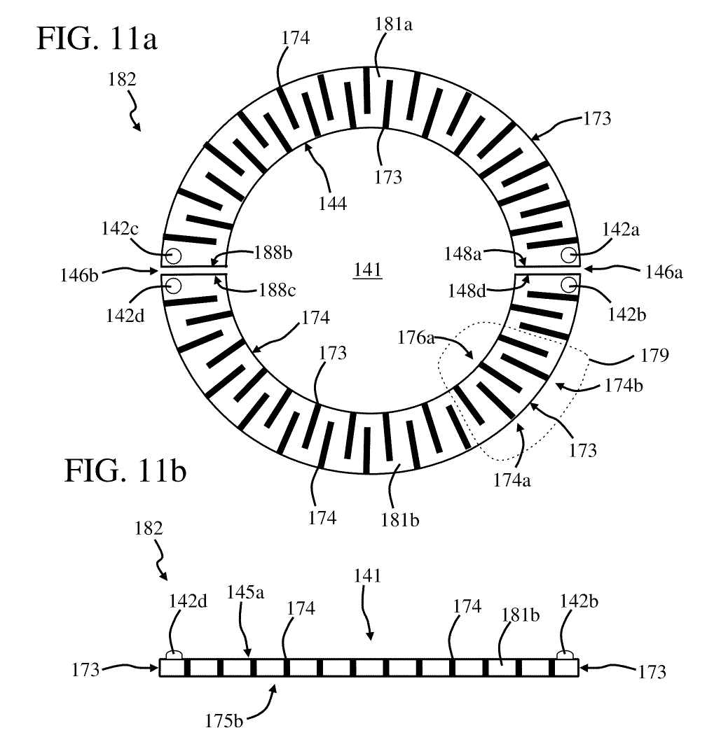

FIGS. 11a and 11b are top and side views, respectively, of one embodiment of a coiled intermediate segmented heater assembly 182. Coiled intermediate segmented heater assembly 182 is a coiled heater assembly because it includes heater coils. In this embodiment, coiled intermediate segmented heater assembly 182 includes heater coil 170 of FIGS. 8a and 8b, as indicated in a region 179 of FIG. 11a. However, in some embodiments, coiled intermediate segmented heater assembly 182 includes heater coil 170a of FIGS. 9a and 9b. In this way, coiled intermediate segmented heater assembly 182 is a coiled heater assembly.

In this embodiment, coiled intermediate segmented heater assembly 182 includes opposed gapped surfaces 175a and 175b, and is bounded by outer peripheral gapped surface 173 and inner peripheral gapped surface 174. Outer peripheral gapped surface 173 extends adjacent to intermediate gap 106 (FIG. 6), and inner peripheral gapped surface 174 extends adjacent to inner gap 105 (FIG. 6). In this way, inner gap 105 is bounded by outer peripheral surface 113 and inner peripheral gapped surface 174. Inner gap 105 is dimensioned to inhibit the ability of current to flow between heater assemblies 181 and 182. Intermediate segmented heater assembly 182 includes central opening 121, which is sized and shaped to receive coiled heater plate 180 (FIG. 6).

In FIGS. 11a and 11b opposed gapped surfaces 142a and 142b and opposed gapped surfaces 142c and 142d are gapped surfaces because inner radial slot 146a and 146b extends therethrough respectively.

In this embodiment, coiled inner segmented heater assembly 182 includes contacts 142a and 142c and contacts 142b and 142d, which are spaced apart from each other by a radial gap 146a and 146b. Coiled inner segmented heater assembly 182 flows heat through opposed surfaces 175a and 175b in response to a potential difference established between contacts 142a and 142c and a potential difference established between contacts 142b and 142d. Coiled inner segmented heater assembly 182 flows heat through opposed surfaces 175a and 175b in response to a current flowing between contacts 142a and 142c and between contacts 142b and 142d.

Radial gap 146a and 146b is a radial gap because it extends along a radial line 104, which extends radially outward from a center 103 of heater plate sub-assembly 110 (FIG. 1a). It should be noted that, in this embodiment, center 103 of heater plate sub-assembly 110 corresponds to a center of heater assembly 100. In this embodiment, radial gap 146a is bounded by opposed radial gap surfaces 148a and 148d and radial gap 146b is bounded by opposed radial gap surfaces 188b and 188c.

Radial gap surfaces 148a and 148d and radial gap surfaces 188b and 188c extend radially outward from center 103 of heater plate sub-assembly 110, and between outer peripheral gapped surface 173 and inner peripheral gapped surface 174.

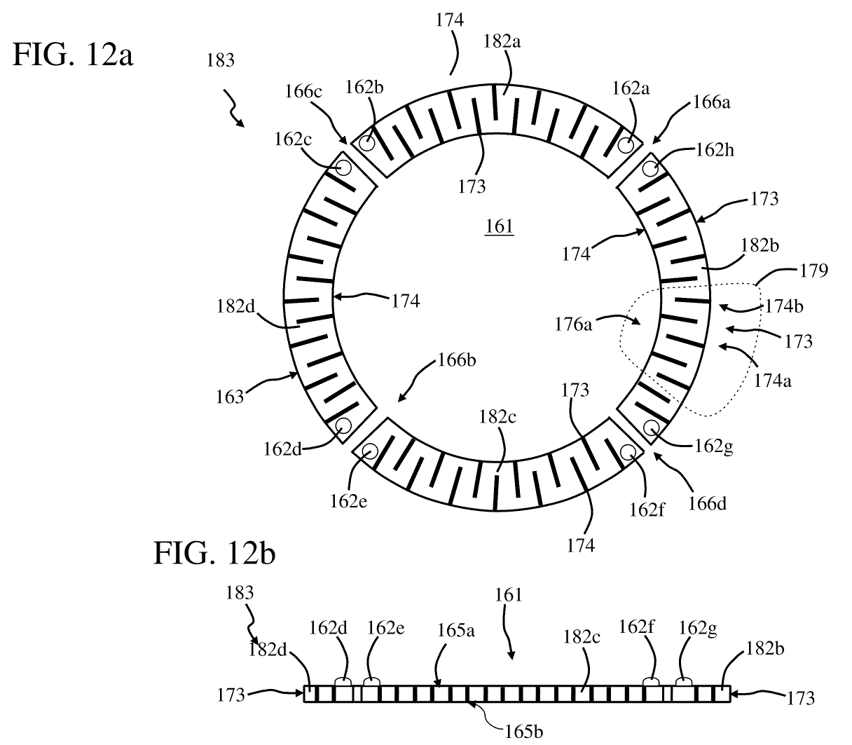

FIGS. 12a and 12b are top and side views, respectively, of one embodiment of a coiled outer segmented heater assembly 183. Coiled outer segmented heater assembly 183 is a coiled heater assembly because it includes heater coils. In this embodiment, coiled outer segmented heater assembly 183 includes heater coil 170 of FIGS. 8a and 8b, as indicated in a region 179 of FIG. 12a. However, in some embodiments, coiled inner segmented heater assembly 183 includes heater coil 170a of FIGS. 9a and 9b. In this way, coiled outer segmented heater assembly 183 is a coiled heater assembly.

In this embodiment, coiled outer segmented heater assembly 183 includes radial gaps 166a, 166bb, 166c and 166d between outer peripheral gapped surface 173 and inner peripheral gapped surface 164. Inner peripheral gapped surface 174 extends adjacent to inner gap 107 (FIG. 6). In this way, inner gap 107 is bounded by outer peripheral surface 143 and inner peripheral gapped surface 164. Inner gap 107 is dimensioned to inhibit the ability of current to flow between heater assemblies 182 and 183. Intermediate segmented heater assembly 183 includes central opening 161, which is sized and shaped to receive coiled heater plate 181a and 181b (FIG. 6).

In this embodiment, coiled outer segmented heater assembly 18e includes contacts 162a and 162b, contacts 162c and 162d and contacts 162e and 162f which are spaced apart from each other by a radial gap 166a, 166bb, 166c and 166d. Coiled outer segmented heater assembly 183 flows heat through opposed surfaces 165a and 165b in response to a potential differences established between contacts 162a and 162b, between contacts 162c and 162d, between contacts 162e and 162f and between contacts 162g and 162h. Coiled outer segmented heater assembly 183 flows heat through opposed surfaces 162a and 162b in response to a current flowing between contacts 162a and 162b, between contacts 162c and 162d, between contacts 162e and 162f and between contacts 162g and 162h, due to a potential difference established between contacts 162c and 162d, a potential difference established between contacts 162e and 162f and a potential difference established between contacts 162g and 162h. Radial gaps 1661, 166b, 166c and 166d are radial gap because it extends along a radial line 104, which extends radially outward from a center 103 of heater plate sub-assembly 110 (FIG. 1a). It should be noted that, in this embodiment, center 103 of heater plate sub-assembly 110 corresponds to a center of heater assembly 100.

It should be noted that a heater assembly can include many different combinations of the components discussed above. For example, the heater assembly can include various combinations of components from heater assembly 100 and 200a. In this way, the heater assembly can be assembled to provide desired heating properties. Several examples of heater assemblies having different combinations of components will be discussed in more detail presently.

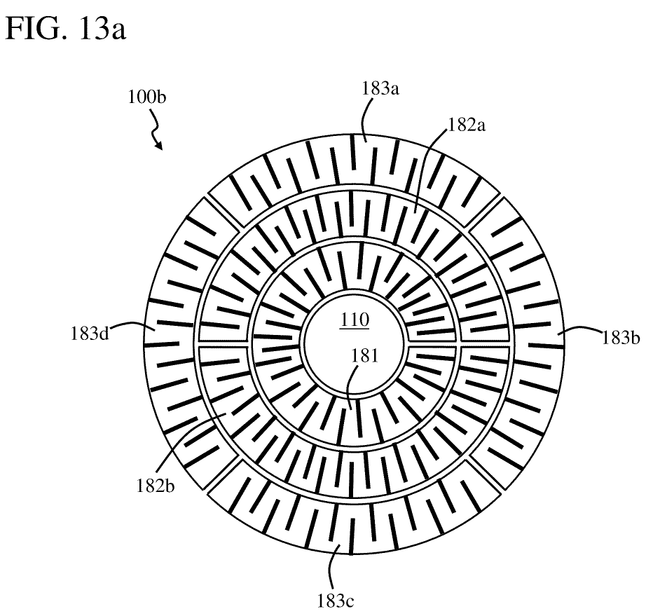

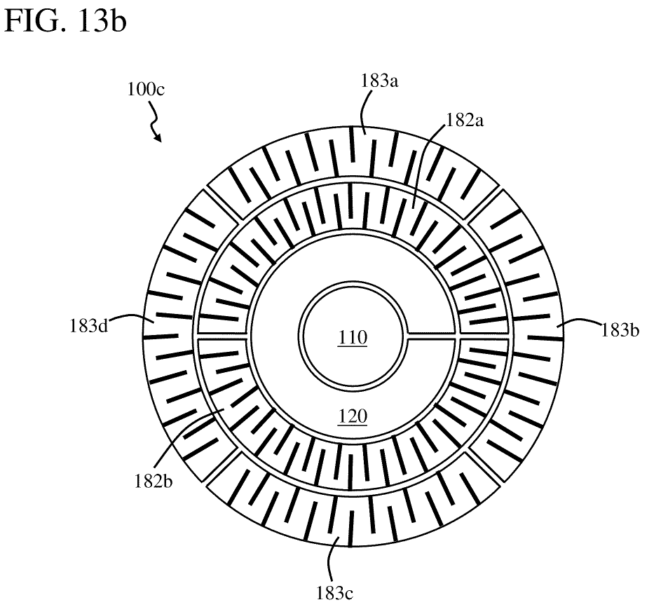

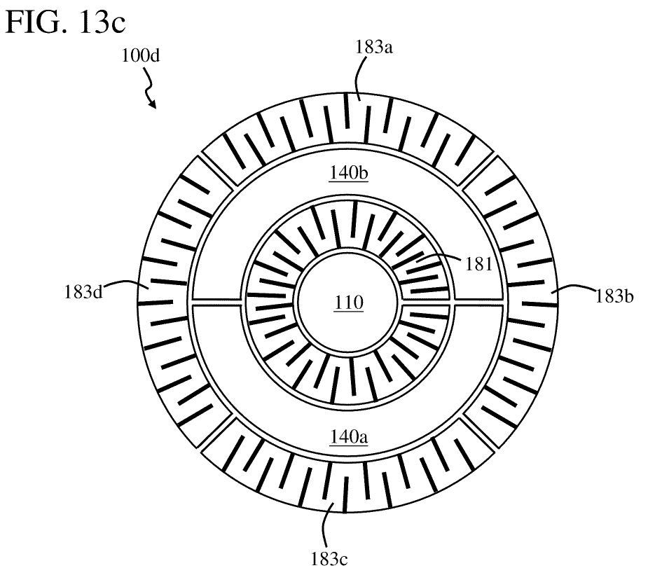

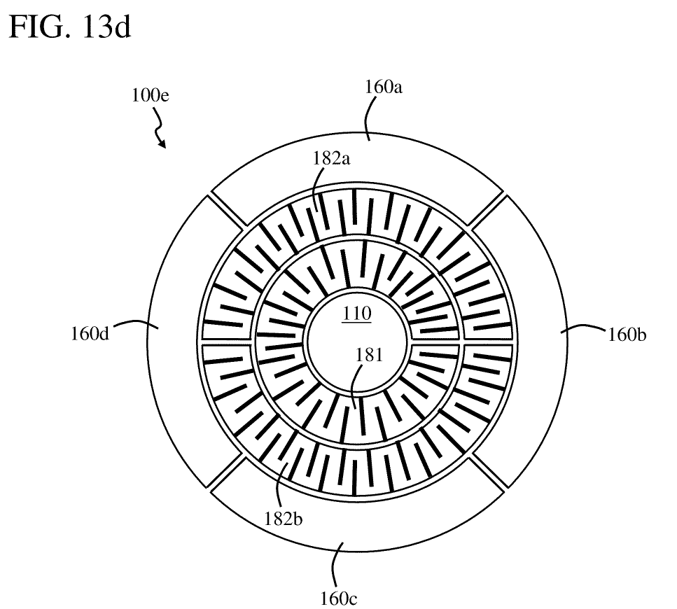

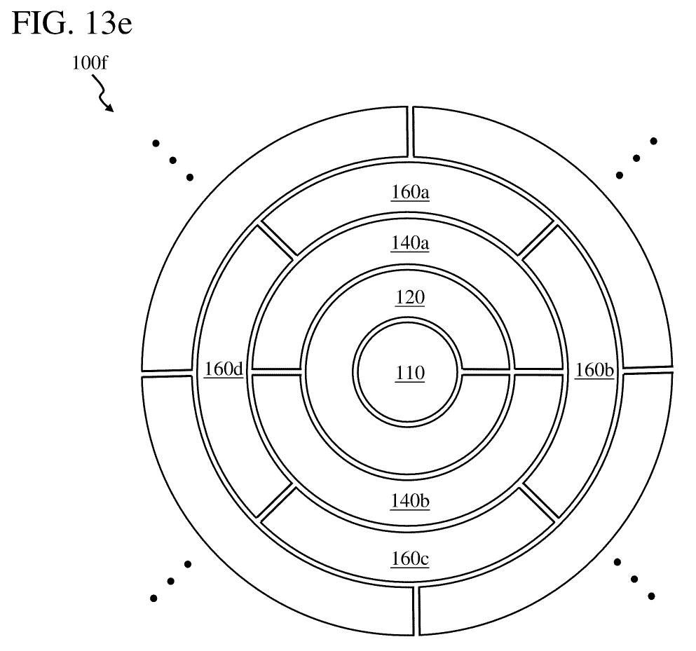

FIG. 13a is a top view of one embodiment of a heater assembly 100b. In this embodiment, heater assembly 100b includes heater plate 110 (FIG. 2a) and coiled inner segmented heater 181 (FIG. 10a). Further, heater assembly 100b includes coiled intermediate segmented heater 182 (FIG. 11a) and coiled outer segmented heater 183 (FIG. 12a). It should be noted that heater assembly 100b can be of uniform thickness, as shown in FIG. 1b, or of non-uniform thickness, as shown in FIG. 1c.

FIG. 13b is a top view of one embodiment of a heater assembly 100c. In this embodiment, heater assembly 100c includes heater plate 110 (FIG. 2a) and inner segmented heater sub-assembly 120 (FIG. 3a). Further, heater assembly 100c includes coiled intermediate segmented heater 182 (FIG. 11a) and coiled outer segmented heater 183 (FIG. 12a). It should be noted that heater assembly 100c can be uniform, as shown in FIG. 1b, or non-uniform, as shown in FIG. 1c.

FIG. 13c is a top view of one embodiment of a heater assembly 100d. In this embodiment, heater assembly 100d includes heater plate 110 (FIG. 2a) and coiled inner segmented heater 181 (FIG. 10a). Further, heater assembly 100d includes intermediate segmented heater sub-assembly 140 (FIG. 4a) and coiled outer segmented heater 183 (FIG. 12a). It should be noted that heater assembly 100d can be uniform, as shown in FIG. 1b, or non-uniform, as shown in FIG. 1c.

FIG. 13d is a top view of one embodiment of a heater assembly 100e. In this embodiment, heater assembly 100e includes heater plate 110 (FIG. 2a) and coiled inner segmented heater 181 (FIG. 10a). Further, heater assembly 100e includes coiled intermediate segmented heater 182 (FIG. 11a) and outer segmented heater sub-assembly 160 (FIG. 5a). It should be noted that heater assembly 100e can be uniform, as shown in FIG. 1b, or non-uniform, as shown in FIG. 1c.

FIG. 13e is a top view of one embodiment of a heater assembly 100f. In this embodiment, heater assembly 100f includes heater plate 110 (FIG. 2a) and inner segmented heater sub-assembly 120 (FIG. 3a). Further, heater assembly 100f includes intermediate segmented heater sub-assembly 140 (FIG. 4a) and outer segmented heater sub-assembly 160 (FIG. 5a). It should be noted that heater assembly 100f can be uniform, as shown in FIG. 1b, or non-uniform, as shown in FIG. 1c.

In this embodiment, heater assembly 100f (FIG. 13e) includes one or more segmented heater assemblies positioned around outer segmented heater sub-assembly 160, as indicated by the ellipses of FIG. 13e. The number of segmented heater assemblies of heater assembly 100f is chosen in response to an area it is desired to heat. In general, the number of segmented heater assemblies of heater assembly 100f increases and decreases as the number of wafers increases and decreases, or as the size of the susceptor increases or decreases respectively.

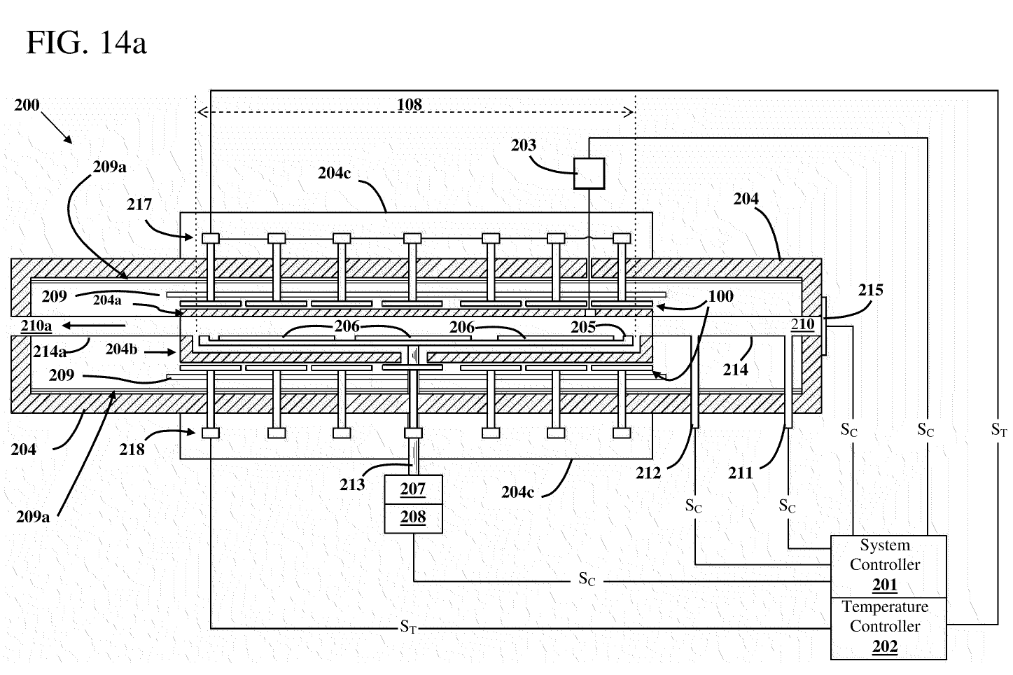

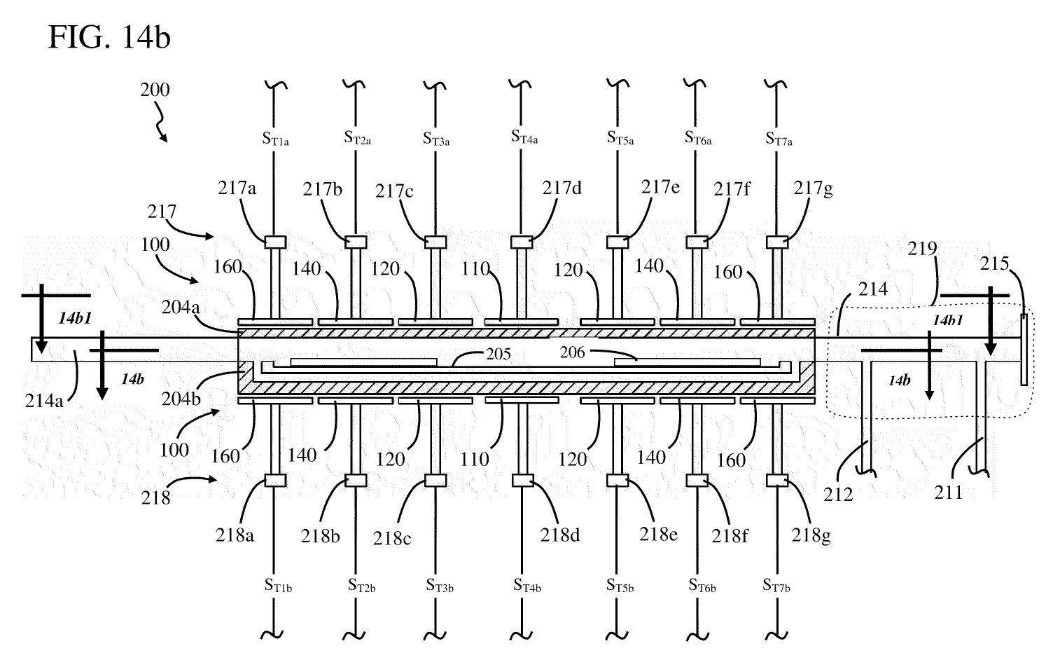

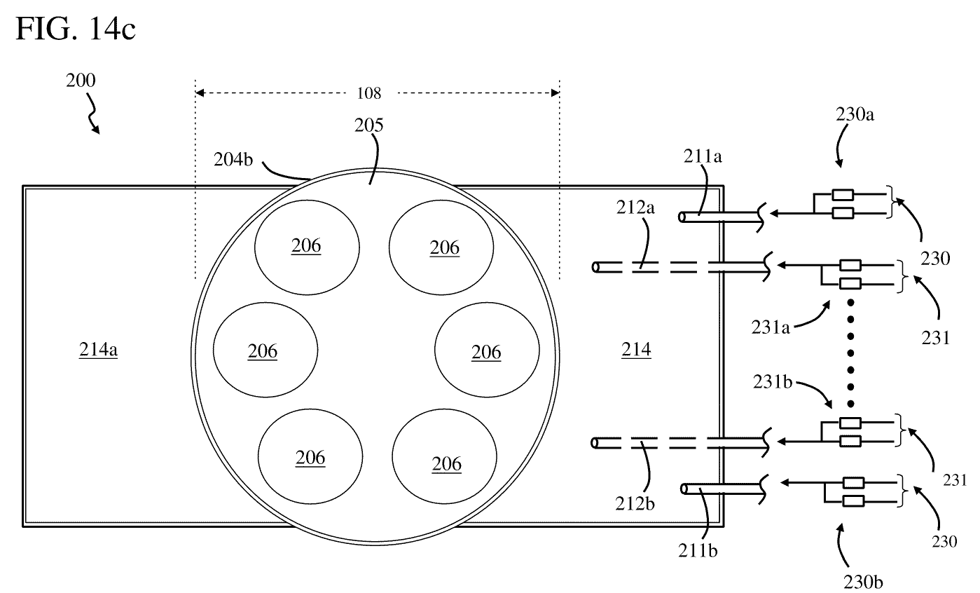

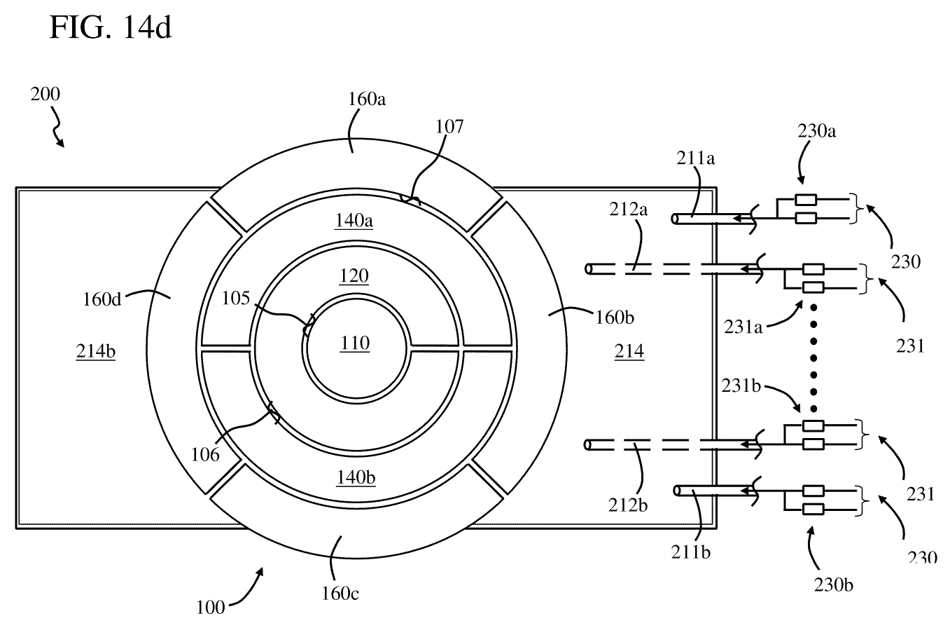

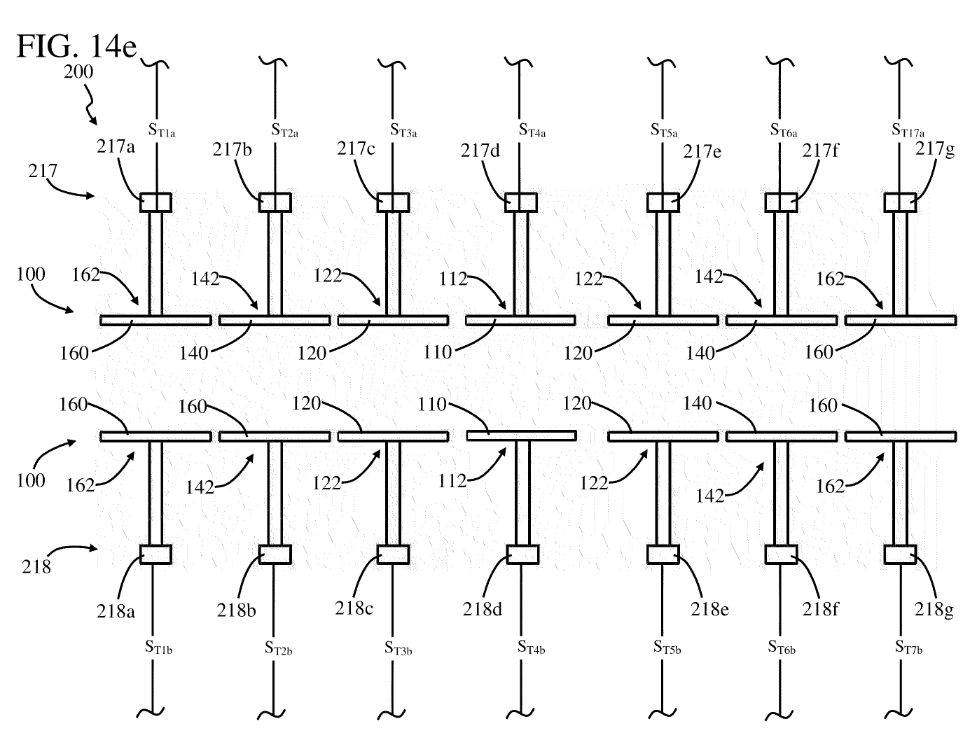

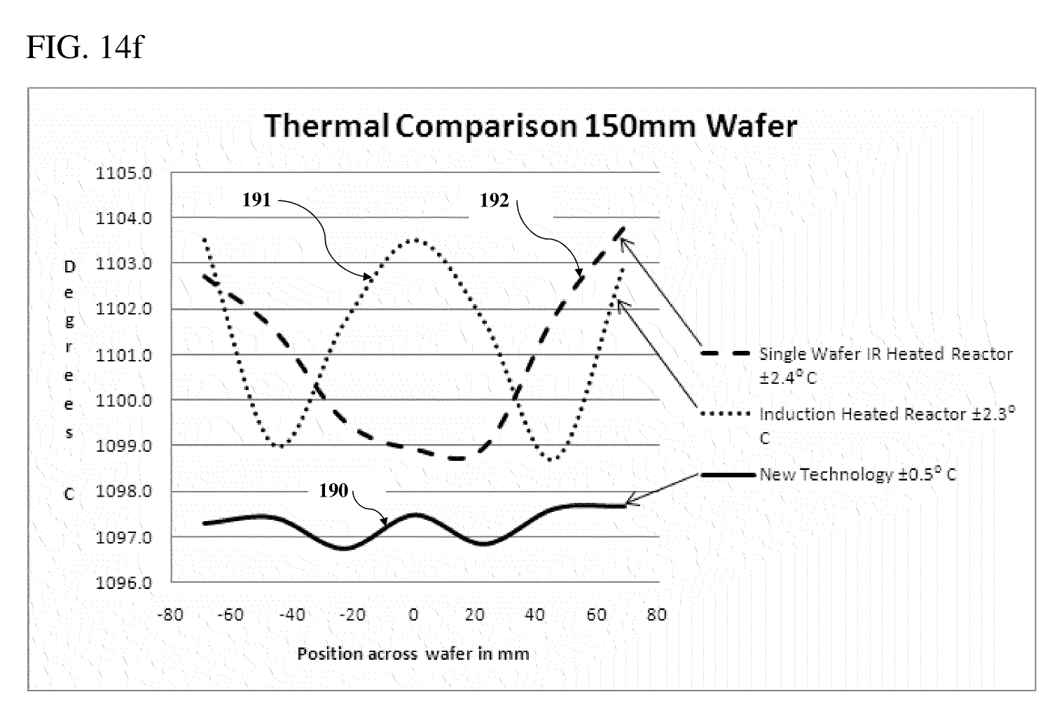

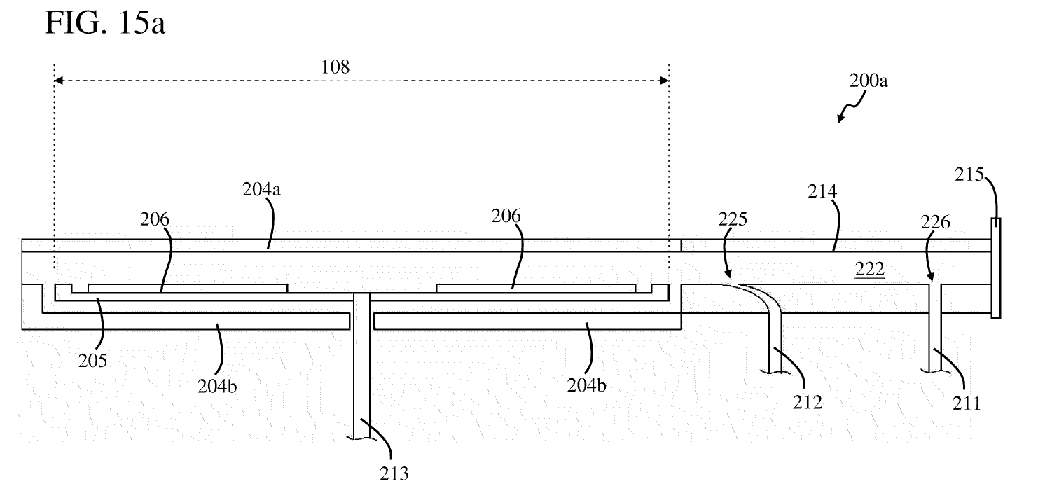

FIG. 14a is a cut-away side view of a deposition system 200. Deposition system 200 can be of many different types, such as a chemical vapor deposition (CVD) system. In one particular, embodiment, deposition system 200 is a metalorganic chemical vapor deposition (MOCVD) system. Deposition system 200 can be used to deposit many different types of material, such as semiconductor material. One particular type of semiconductor material that can be deposited using deposition system 200 is a semiconductor nitride. There are many different types of semiconductor nitrides that can be deposited using deposition system 200, such as gallium nitride and alloys thereof. There are many different alloys of gallium nitride, such as indium gallium nitride and aluminum gallium nitride, among others.

It should be noted that the materials deposited using deposition system can be used in many different types of semiconductor devices, such as electrical devices and optoelectronic devices. Some examples of electrical devices include diodes and transistors, among others. Examples of optoelectronic devices include light emitting diodes, semiconductor lasers, photo-detectors and solar cells, among others.

In this embodiment deposition system 200 (FIG. 14a) includes:
a. A reactor housing 204 usually fluid cooled and constructed from materials such as quartz, aluminum or stainless steel,
b. A reactor chamber 204a top and 204b bottom bounded by housing 204,
c. A process zone 108 bounded by process chamber 204a and 204b,
d. A rotatable susceptor 205 of one or more pieces carried by pedestal 213 supporting the wafer(s) 206 in the process zone 108, further a rotation motor 207 and a susceptor lift/wafer lift 208 are operatively coupled to pedestal(s) 213,
e. A heater assembly 100 as in FIG. 1a for example, mounted above and below the reactor chamber 204a/204b to provide adjustable amounts of heat to the reactor chamber 102, susceptor 205 and wafers 206,
f. A temperature/thermal sensor(s) 203 sensing the wafer(s) 206, susceptor(s) 205 or heater assembly(ies) 100 or combinations thereof; further, temperature sensors include but are not limited to thermocouples, reflectometers or pyrometers. Purged sealed ports/view ports outside of the reactor chamber environment may be arranged to accommodate temperature/thermal sensor(s) 203 such as thermocouples and or pyrometers. There may also be holes (not shown) in reactor chamber 204a/204b for the temperature sensor(s) 203.
g. A system controller 201 and a temperature control system 202 providing adjustable power signals S_{T} to the heater assembly(ies) 100 via heater terminals 217 and 218, further temperature controller 202 receives temperature signals S_{c} from temperature/thermal sensor 203 via system controller 201. Further, system controller 201 controls the movement of sealed access door 215 to allow loading and unloading the wafer and sealing of the loading port 210. System controller 201 also controls wafer movement, process gas sequencing and gas flow to reactor chamber 204a/204b, and other functions such as purge flows, process times, cooling flows and safety controls. Further, system controller 201 also controls rotation motor 207 and susceptor lift mechanism 208 via signal S_{c}.
h. Heat shields 209 and heat shield liners 209a disposed between the heater assembly(ies) 100 and the reactor housing to minimize heat transfer/loss from the heater assembly(ies) 100 into the reactor housing 204, and provide reradiating surfaces to heater assembly(ies) 100 and reactor chamber 204a/204b. In an embodiment, reactor chamber 204a/204b, susceptor(s) 205 and heat shield(s) 209 and 209a are made of a material such as but not limited to quartz, silicon carbide and silicon carbide coated graphite. Further, liner heat shield 209a is arranged to protect the interior surfaces of housing 204.
i. The amount of heat provided by each heater sub-assembly such as heater 110, 120, 140 and 160 of the heater assembly 100 is controllable. The amount of heat provided by a heater sub-assembly such as heater 110, 120, 140 and 160 of the heater assembly 100 is adjustable to adjust the temperature of the reactor chamber 204a/204b, the susceptor 205 and or the wafer(s) 206. The amount of heat provided by each heater sub-assembly such as heater 110, 120, 140 and 160 of the heater assembly 100 is adjustable to adjust the temperature of the inlet gas. The amount of heat provided by each heater sub-assembly such as heater 110, 120, 140 and 160 of the heater assembly 100 is adjustable in response to adjusting a current flow therethrough.
j. The deposition system 200 is capable of operating at pressures above or below atmospheric pressure.

In this embodiment deposition system 200 (FIG. 14a) includes:
k. A gas inlet and wafer loading duct 214 and a gas exhaust duct 214a connected respectively to inlet/loading port 210 and exhaust port 210a,
l. Upstream and downstream gas inlet conduit(s) 211 and 212 are connected to gas inlet and loading duct 214 to supply process gases to reactor chamber 204a/204b. The gas inlet and loading duct 214 also serves as access for loading and unloading the wafer(s) 206 to and from the reactor chamber 204a/204b through loading port 210 via the sealed access door 215 controlled by system controller 201. Gas exhaust duct(s) 214a removes exhaust gases from reactor chamber 204a/204b out exhaust port 210a. Gas inlet and loading duct(s) 210 and gas exhaust duct(s) 210, susceptor 205 and reactor chamber 204a/204b are made of one or more pieces of materials such as but not limited to silicon carbide, and silicon carbide coated graphite.
m. A top and bottom sealed/purged cover box 204c is sealed to housing 204 enclosing electrical terminals 217 and 218 which supply adjustable power signals to heater assembly(ies) 100 (only one power signal to the top and bottom heater assembly 100 is shown for simplicity).

FIG. 14b is cross sectional view of the heater assemblies 100 such as shown in FIG. 1a, FIG. 1b, and FIG. 1d showing heater sub-assemblies 110, 120, 140 and 160 including process chamber 204a/204b, susceptor 205 and wafers 206 and the gas inlet and loading duct 210, the upstream gas inlet conduit 211 and the downstream gas inlet conduit 212 and exhaust duct 210b of deposition system 200. In this embodiment the temperature control system 202 is connected to each heater sub-assembly 110, 120, 140 and 160 of heater assembly 100 top and bottom by heater terminals 217ₐ through 217_{g} and 218ₐ through 218_{g} respectively, thereby providing adjustable power signals S_{T1a} through S_{T7a} and S_{T1b} through S_{T7b} to each heater sub-assembly 110, 120, 140 and 160 of heater assembly 100 both top and bottom (only one connection is shown for each heater for the sake of simplicity). Each heater sub-assembly 110, 120, 140 and 160 of top and bottom heater assembly 100 provides adjustable amounts of heat to the top and bottom of the reactor chamber 204a/204b, to susceptor 205 and wafers 206 on susceptor 205 of process zone 108 of disposition system 200. The proper selection of heater sub-assembly shape and number heater sub-assemblies as previously discussed provides the ability to produce a heat/temperature profile across the susceptor 205 in process zone 108 resulting in a temperature profile as depicted in FIG. 1g.

FIG. 14c is cross sectional plan view along cut line 14b-14b of FIG. 14b of deposition system 200 showing wafer(s) 206 on the rotatable susceptor 205 in process zone 108. In this embodiment, a plurality of gas(es) 230 and 231 are controlled by gas flow control devices and on/off valve(s) 230a through 230b and 231a through 231b that control the flow of the plurality of gases 230 and 231. The plurality of gas(es) 230 and 231 are then introduced into to the gas inject conduits 211a through 211b and 212a through 212b which feed the plurality of gas(es) 230 and 231 gas into the inlet/loading duct 214 and then over the wafers 206 on susceptor 205 at an adjustable heat/temperature as discussed above in process zone 108. This provides multiple sub-process zones (not shown) of process zone 108 in which the heat/temperature and the gas flow(s) of the sub-process zones are controlled in order to deposit layers of uniform thickness and composition on the wafer 206 on rotating susceptor 205. Effluent gases exit via exhaust duct 214a.

FIG. 14d is a cross section plan view of heater array 100 along cut line 14b1-14b1 of FIG. 14b of deposition system 200 showing a representative upper heater assembly 100 (Reference FIG. 1a) consisting of heater sub-assemblies 110, 120, 140a and 140b and 160a, 160b, 160c and 160d. The annular gaps 105, 106 and 107 as previously described are also shown. Again, a plurality of gas(es) 230 and 231 are controlled by gas flow control devices and on/off valve(s) 230a through 230b and 231a through 231b that control the flow of the gases 230 and 231. The plurality of gas(es) 230 and 231 are then introduced into the gas inject conduits 211a through 211b and 212a through 212b which feed the plurality of gas(es) 230 and 231 gas inlet/loading duct 214. The gasses then pass through the reactor chamber 240/240a where the plurality of gasses 230 and 231 are selectively heated by the sub-assembly heaters of heater assembly 100 both top and bottom along with heating the wafers 206 and susceptor 205 of FIG. 14c to provide a deposition of uniform thickness and composition on the wafer(s) 205 while minimizing the wafer temperature differential in the vertical and horizontal direction. Effluent gases exit via exhaust duct 214a.

FIG. 14e is an expanded view of the upper and lower heater arrays 100 of deposition system 200. Each heater 110, 120, 130 and 140 has an electrically conductive transitory connection 112, 122, 142 and 162 designed to minimize heat transfer but maximize electrical conduction in the transition from heater materials to electrical heater terminals 217ₐ through 217_{g} and 218ₐ through 218_{g} which are then connected to adjustable power signals S_{T1a} through S_{T7a} and S_{T1b} through S_{T7b} to each heater sub-assembly 110, 120, 140 and 160 of heater assembly 100 both top and bottom individually controlled or controlled in groups/zones. This is accomplished by arranging temperature sensor(s) 203 from FIG. 14a and heater sub-assemblies 110, 120, 140 and 160 to establish independently controlled zones of heat for example, of the front, rear, left, right and center sections (not shown) of the process zone 108 thereby compensating for the different thermal requirement/radiation losses within each zone to produce a uniform temperature across and through the susceptor 205 and wafer(s) 206. The bottom heater assembly 100 may or may not be parallel and coincident to the top heater assembly 100. The ability to control the temperatures in general of the individual heater sub-assemblies or in multiple independent groups of heater sub-assemblies is a significant advantage of this invention as can be seen in FIG. 14f which shows a temperature profile 190 of a wafer in a system as describe herein in FIG. 14a versus the temperature profile 191 of a wafer of a induction heated prior art system and a temperature profile 192 of a wafer in an IR lamp heated prior art system. This “new technology” describe herein far exceeds the others with a ±0.5° C. temperate uniformity across a 150 mm wafer versus ±3.1° C. and ±2.4° C. for the induction heated and IR lamp heated system respectively.

FIG. 15a is a side cross-sectional view of reactor chamber 204a/204b of deposition system 200a. FIG. 15b is an expanded cross sectional side view of the gas injection scheme as defined by region 219 of FIG. 14b. The upstream gas inlet conduits 211 is disposed so as to independently inject/spread an individually controlled flow of a process gas(es) as described in FIGS. 14c and 14d, being either carrier and or reactant gases 230, perpendicularly into the interior of gas inlet and loading duct 214 at port 226 being a hole, multiple holes, or slit(s) of a size 228 such that a substantially laminar flow/gas velocity profile 236 of the carrier and or reactant gases is established with an attendant boundary layer 232. Downstream gas inlet conduit(s) 212 is positioned downstream of the upstream gas inlet conduit 211 in the laminar flow region. Downstream gas inlet port(s) 225, may be designed as a slit(s) or hole(s) of size 227 with a upstream dimension 227a and a downstream dimension 227b shaped to inject a process and or carrier gas 238 utilizing the Coanda effect* substantially tangentially into the boundary layer 232 of the laminar flow/gas velocity profile 236 produced by upstream gas inlet port(s) 226 and gas inlet and loading duct 214 such that the gasses injected by downstream gas inlet port(s) substantially attach themselves to the lower inside surface of gas inlet and loading duct 214 and flow in streams closely over and parallel to the inside bottom surface of the gas inlet and loading duct 214 and then over the top surface of wafers 206 on susceptor 205. The embodiment of this gas introduction scheme maximizes the reaction efficiency of the plurality of process gas(es) 231 with the wafer(s) 206 on susceptor 205 thereby maximizing the deposition rate and conversion efficiency of gas(es) 238 and minimizing reactant gas depletion across the susceptor. This tangential Coanda gas introduction systems is also capability of separately delivering reactant gases 230 and 231 to the process zone 108 (such as ammonia and Trimethylgallium commonly used in manufacturing High Brightness LEDs, these reactant can also be delivered to the process zone 108 via separate Coanda port(s) 225 both methods which eliminate premature gas reactions which result in clogging, plugging, particle generation in the gas delivery system or reactor chamber.
n. *(The Coanda effect is briefly described as the tendency of a fluid jet to be attracted to a nearby surface^{[1]}. The principle was named after Romanian aerodynamics pioneer Henri Coand\check{a}, who was the first to recognize the practical application of the phenomenon in aircraft development. Much is published in literature and text books on aeronautical boundary layer injection, the Coanda effect and boundary layer deposition physics). ¹From Wikipedia

FIG. 15c is a pictorial view of the one of the upstream gas inlet ports 226 and one of the downstream gas inlet ports 225.

FIG. 15d is an expanded view along cut line 15d-15d of FIG. 15c of one the upstream gas inlet port 226 which is fed by gas inlet conduit 211 and the tangential inject port 225 which is fed by gas inlet conduit 212.

FIG. 15e is a plan view of the upstream gas injection system of deposition system 200. In this embodiment a plurality of gasses are controlled by a plurality of flow control devices and on off valves 231a, 231b, 231c, 231d and 231e feeding upstream conduits 211a, 211b, 211c, 211d and 211e in turn feeding tangential gas injection port assembly 226a, 226b, 226c, 226d and 226e wherein the gas is injected into inlet gas inlet and loading duct 214 then over the tangential gas injection port assembly 229a, 229b, 229c, 229d and 229e. The plurality of gases then passing over the wafers 206 on susceptor 205 in reactor chamber 204b and then out the exhaust duct 210a.

FIG. 15f is a plan view of the downstream gas inject embodiment of deposition system 200. In this embodiment a plurality of gasses are controlled by a plurality of flow control devices and on off valves 230a, 230b, 230c, 230d and 230e feeding downstream conduits 212a, 212b, 212c, 212d and 212e in turn feeding tangential gas injection port assembly 229a, 229b, 229c, 229d and 229e wherein the gas is injected into gas inlet and loading duct 214 substantially tangentially out of ports 225a, 225b, 225c, 225d, and 225e then over the wafers 206 on susceptor 205 in reactor chamber 204b and then out the exhaust duct 214a.

The upstream and downstream gas inlet conduit(s) 211 and 212 are constructed of one or more pieces of a suitable materials such as silicon carbide, silicon carbide coated graphite or graphite or combinations thereof. The number of upstream conduits 211 and downstream conduits 212 can be added or subtracted as determined by the process deposition requirements of the deposition system 200 and the size of the susceptor 205 and wafer(s) 206.

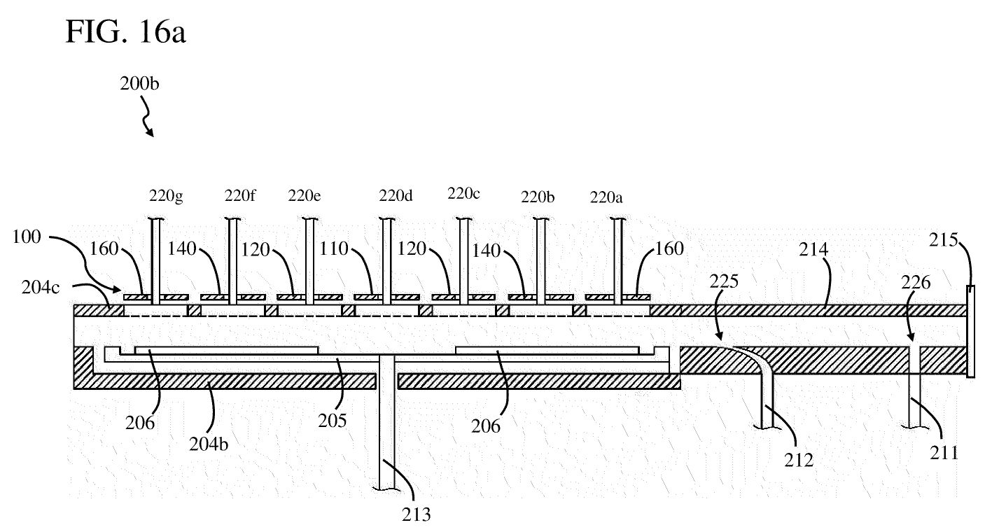

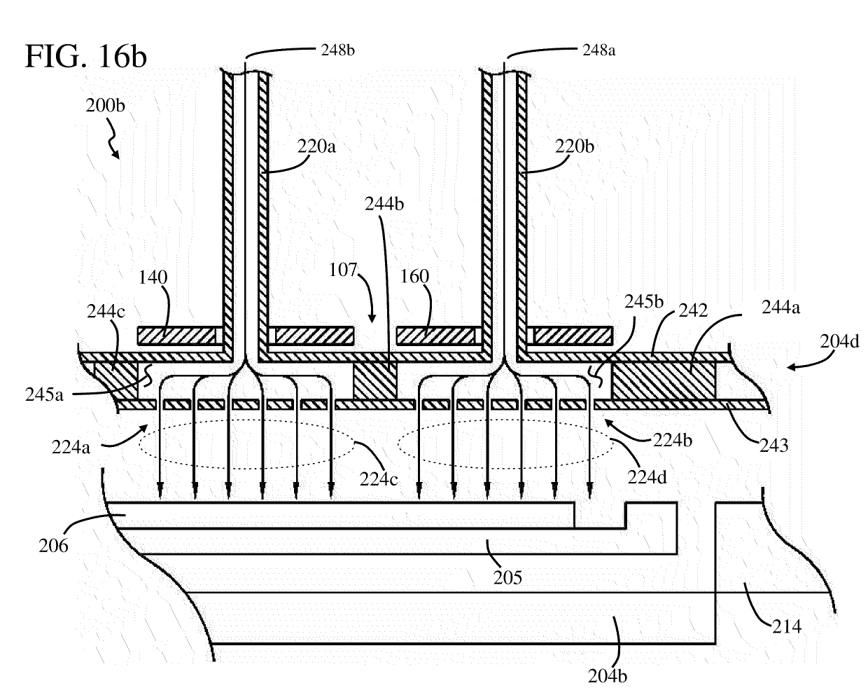

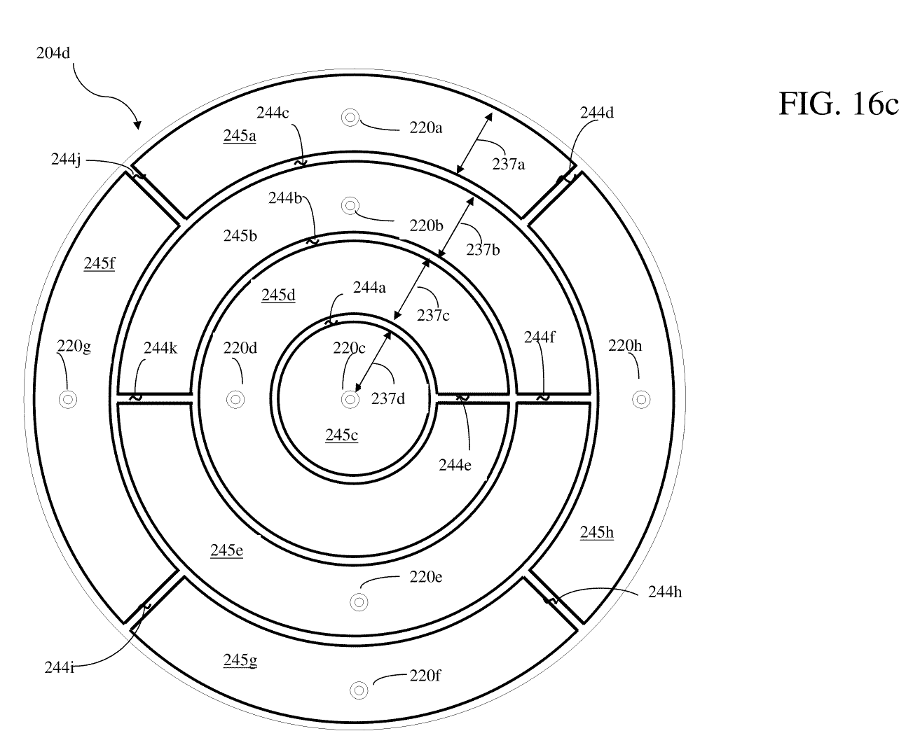

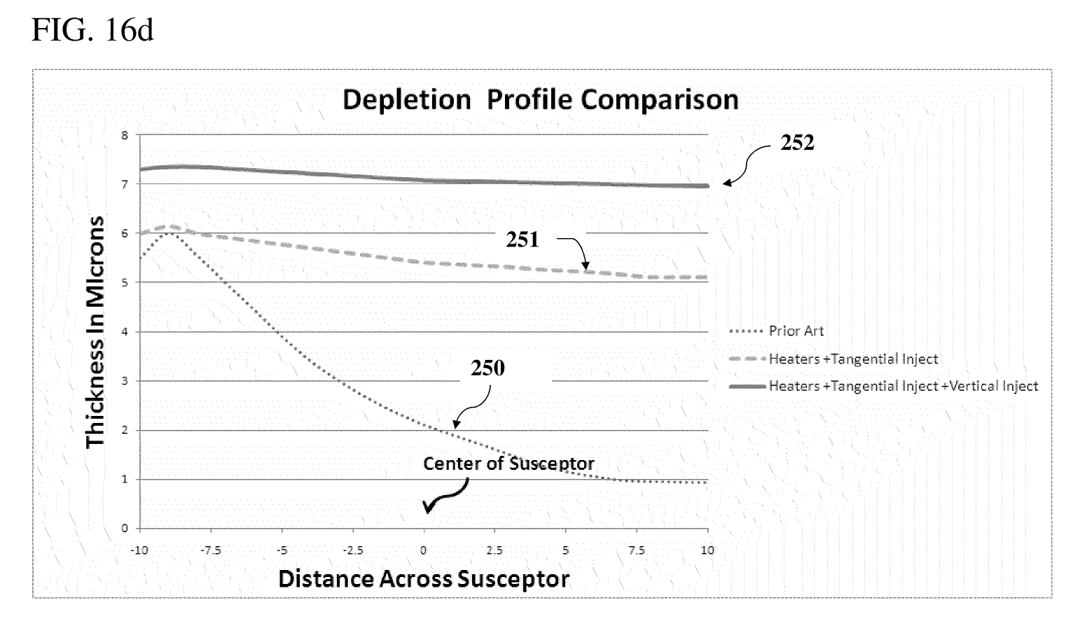

FIGS. 16a, 16b and 16c shows a cross sectional view, an exploded cross sectional view and plan view respectively of a vertical gas inject scheme of deposition system 200b. In this embodiment, a double walled multi gas chamber upper plate 204d replaces the upper reactor chamber (plate) 204a of FIG. 14a. below heater assembly 100a. A plurality of separate gas inlet conduits 220a, 220b, 200c, 220d, 220d, 220e, 220f, 220g on the uppermost plate 242a each connected to a plurality of gas channel circular segments, circles or rings 245a, 245b, 245c, 245d, 245e, 245f, 245h and 245g each having a uppermost plate 242 and bottom plate 243 and separators 244 forming a gas cavity/plenum(s) 245a and 245b, for example as shown in FIG. 16b, with an array of holes 224a and 224b in bottom plate 243 for vertically impinging inlet gas(es) 224c and 224d (C onto the wafers 206 on susceptor 205 or comingling with the horizontal gas flow from ports 226 and or 225.

Each gas inlet ports 220a, 220b, 200c, 220d, 220d, 220e, 220f, 220g are connected to a gas flow control devices such as valves, mass flow controllers and or metering devices (not shown) for independently controlling a plurality of inlet gas(es) 248a and 248b (FIG. 16b) for example to each cavity/plenum 245a, 245b, 245c, 245d, 245e, 245f, 245h and 245g. The inlet gas(es) 248a and 248b may be reactant and or carrier gas(es). The cavity/plenum 245a, 245b, 245c, 245d, 245e, 245f, 245h and 245g can be of various width(s) 237a, 237b, 237c and 237c as shown in FIG. 16c. The array of holes 224a and 224b for example, may or may not be uniform in size and spacing, in order to provide a uniform vertical flow of gas(es) 224c and 224d to the wafer(s) 206 on susceptor 206 from the circular segments. This vertical flow 224c and 224d for example may comingle with the horizontal gas flow 235 of FIG. 15b in reactor chamber 204a/204b at the surface of the wafer(s) 206. This enables increased growth rates of the gas(es) from gas ports 225 and 226, and or a means to separately introduce reactant gases that need to substantially combine/react only at the surface of wafer 206 to chemically vapor deposit compounds. Adjusting the flow of inlet gas(es) 248a and 248b can be used to vary and tune the deposition rate of the reactant gases and or those from gas ports 225 and 226. Another feature of this embodiment is the circular upper heater assembly previously described in FIG. 14a is positioned parallel/close to the uppermost plate 204c. Heater sub-assemblies 140 and 160 of upper heater assemblies 100 may be associated with for example gas channel segments 245a and 245b together forming a controlled deposition zone (not shown) in which the temperature and flow can be independently controlled for tuning the deposition rate on the wafer 206. An additional beneficial effect is that heaters 140 and 160 for example, preheat the inlet gas(es) 248a and 248b in cavity 245a and 245b before it arrives at the surface of wafer 206. This minimizes the thermal impact of a cold gas on the wafer 206 and improving the reaction rate and minimizes the potential of wafer warpage that is a problem with prior art systems. Top plate 204c may be constructed of materials such as but not limited to silicon carbide, silicon carbide coated graphite or graphite.

FIG. 16d shows a comparison of the deposition profile across a non-rotating susceptor of a deposited layer for:
o. a prior art deposition system 250,
p. a deposition profile 251 of a deposition system 200a as described in FIGS. 14a, 14b, 14c and 14d and FIGS. 15a, 15b, 15c and 15d herein using the heating system discussed herein and the gas injection embodiment of FIGS. 15a, 15b, and 15c
q. a deposition profile 252 of depositions system 200b as described in FIG. 16a, FIG. 16b, FIG. 16c. herein, the gas injections system of FIG. 15 and the vertical gas introduction technique of FIG. 16a, FIG. 16b and FIG. 16c.
   This deposition profile is commonly called the “depletion curve” and defines the deposition thickness across the susceptor as the reactant gases are “used-up” or depleted as they travel across the susceptor. As can be seen the technology described herein has a much more favorable depletion curve that results in a more uniform deposition across the susceptor and therefore a more uniform deposition on the wafers 206.

Deposition systems in general all require a cleaning step for removing extraneous deposits on the internal surfaces of the reactor process chamber, the susceptor and gas inlet and exhaust conduits/ducts left behind by the deposition process. In some cases this is an insitu gas phase, high temperature cleaning step. In other cases of prior art, the cleaning step may require a complete reactor shutdown and disassembly to replace and or clean these parts. This removal and cleaning is one of the biggest reasons for reactor internal parts breakage and damage, reactor contamination and downtime. Also, the prior art system's seals may have be replaced due to damage caused by the high temperatures and exposure to deposition and etchant gases. Every time this cleaning takes place, a requalification of the process is required. This cleaning and requalification can take up to 16 hours which is lost production time. In the case of the MOCVD systems, the gas phase cleaning step of the residual deposits is ineffective and therefore the internal parts of the reactor are removed, cleaned and or replaced with new parts, which is very costly. The heating embodiment of deposition system 200 (FIG. 14a), the materials of construction of the reactor chamber 204/204b, the gas injections systems (FIG. 15a, b, c, d and FIG. 16a, b and c) allow for a more effective means of introducing a cleaning gases and or using different etchant/cleaning gases via 230 and 231 (FIG. 15e and f) enhancing the effectiveness of the insitu gas phase cleaning (etching) of the deposits left behind thereby improving system uptime.

It is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods and systems for carrying out aspects of the present invention. It is important, therefore, that the claims be regarded as including such equivalent constructions insofar as they do not depart from the spirit and scope of the present invention.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

1. An apparatus, comprising: a segmented heater assembly which provides first and seconds amount of heat in response to receiving first and second signals, respectively; wherein the first and second amounts of heat are adjustable in response to adjusting the corresponding first and second signals.

2. The apparatus of claim 1, wherein the segmented heater assembly includes an inner segmented heater sub-assembly and an intermediate segmented heater sub-assembly spaced apart and from each other by an intermediate gap.

3. The apparatus of claim 1, wherein the segmented heater sub-assembly includes a first inner radial slot and a first outer radial slot.

4. The apparatus of claim 1, wherein the inner segmented heater sub-assembly has a thickness proximate to the intermediate gap that is smaller than a thickness away from the intermediate gap.

5. The apparatus of claim 1, wherein the intermediate segmented heater sub-assembly has a thickness proximate to the intermediate gap that is greater than a thickness away from the intermediate gap.

6. The apparatus of claim 1, wherein the inner segmented heater sub-assembly is a coiled inner segmented heater sub-assembly and the intermediate segmented heater sub-assembly is a coiled intermediate segmented heater assembly spaced apart by a gap.

7. The apparatus of claim 1, wherein the inner segmented heater sub-assembly and the intermediate segmented heater sub-assembly includes inner and outer radial slots.

8. The apparatus of claim 1, having an inner, one or more intermediate and an outer radial segmented heater sub-assembly(ies) comprising a heater assembly spaced apart by intermediate and outer gaps respectively wherein the respective amounts of heat are adjustable in response to adjusting the respective signals.

9. The apparatus of claim 8, wherein the inner segmented heater sub-assembly is a coiled inner heater assembly of a constant or varying cross sectional width and thickness proximate to the center and proximate to the outside of the heater producing an amount of heat proportional to the resistance produced by the cross sectional width and thickness.

10. The apparatus of claim 8, comprising a heater sub-assembly which provides first and second amounts of heat in response to receiving first and second signals, respectively; wherein the first and second amounts of heat are applied to gases from an upstream and downstream gas flow.

11. An apparatus, comprising: a housing enclosing a radial segmented heater assembly; a heater assembly that may be disposed parallel or rotationally coincident to the bottom and or top of an enclosed reactor chamber having a duct for gas introduction and wafer loading and a duct for exhaust gas; the reactor chamber containing a susceptor supporting wafer(s) coupled to a rotation motor and a lift(s) for the susceptor and or wafers wherein deposition processes are performed on a wafer(s).

12. The apparatus of claim 11, wherein the top and bottom heater assembly being adjustable in size number of heater sub-assemblies to provide zones of precise temperature adjustability and control.

13. The apparatus of claim 11, wherein the opposite side the of the radial segmented heater assembly from the reactor chamber has one or more heat shields of one or more pieces to minimize heat loss from the heaters assemblies.

14. The apparatus of claim 11, comprising heaters with each heater end having an electrical post/connection for the adjustable signal.

15. The apparatus of claim 11, wherein a plurality of flow controlled gases are introduced into the process chamber from a plurality of upstream and or downstream conduits.

16. The apparatus of claim 11, wherein the plurality of flow controlled gases along with adjustable amounts of heat produce defined temperature and flow zones that produce zones of adjustable deposition rates and composition of deposited layers on the wafer(s).

17. An apparatus, comprising: a plurality of upstream and downstream process gas inlet port(s) configured whereby a second flow controlled process gas(es) is introduced into the boundary layer flow stream of a first flow controlled process gas via boundary layer injection utilizing the Coanda effect to control and or increase the deposition rate and control the composition of the deposited layer on the wafer and decrease the reactant gas depletion rate across the susceptor.

18. An apparatus, comprising: a process chamber top plate having a enclosed radial segmented plenum(s) with a flow controlled process gases gas inlet(s) in the uppermost plate feeding the plenum and an array of holes in the lower plate of the radial segmented plenum for impinging process gas(es) vertically down onto the wafer(s) on the susceptor in the process chamber that may comingle with the process gases at the wafer surface to form deposited layers on the wafer(s) thereby adjusting the deposition rate and composition of the deposited layer on the wafer; the vertical gases being adjustably heated by the radial segmented heater assembly.

19. The apparatus of claim 11, wherein the vertically flow controlled gas being heated by the adjustable amounts of heat from the heaters “presses” the gas(es) vertically down on areas of the wafer and or susceptor enhancing the deposition rate on the wafer.

20. The apparatus of claim 11, wherein process gases such as but not limited to hydrogen and chlorine or fluorine containing compounds in situ cleans or removes extraneous chemical deposits out the exhaust from the depositions that occur in the process chamber, and or on gas inlet and exhaust ducts and or on the susceptor.

21. The apparatus of claim 5, designed to support above or below atmospheric pressure processing inside the housing.

22. The apparatus of claim 11, having radial segmented heaters, the process chamber, the ducts for gas introduction and gas exhaust, the rotatable susceptor being constructed of materials such as but not limited to silicon carbide coated graphite.
